(19) United States
(12) Patent Application Publication
(10) Pub. No.: US 2026/0353655 A1
(43) Pub. Date: Nov. 5, 2026

(54) THREE-DIMENSIONAL SEMICONDUCTOR MEMORY DEVICE INCLUDING VERTICALLY STACKED CONDUCTIVE LINES AND ELECTRONIC SYSTEM INCLUDING THE SAME

(71) Applicant: Samsung Electronics Co., Ltd., Suwon-si (KR)

(72) Inventor: Kang Lib Kim, Suwon-si (KR)

(73) Assignee: Samsung Electronics Co., Ltd., Suwon-si (KR)

(21) Appl. No.: 19/386,849

(22) Filed: Nov. 12, 2025

(30) Foreign Application Priority Data
May 2, 2025 (KR) 10-2025-0057944

(51) Int. Cl. H10B 43/27; H10B 41/10; H10B 41/27; H10B 41/35; H10B 41/41; H10B 43/10; H10B 43/35; H10B 43/40

(52) U.S. Cl. CPC H10B 43/27; H10B 41/10; H10B 41/27; H10B 41/35; H10B 41/41; H10B 43/10; H10B 43/35; H10B 43/40

(57) ABSTRACT

A three-dimensional semiconductor memory device includes a stacked structure including gate electrodes stacked along a first direction, the stacked structure including a cell region and an extension region, a vertical structure in the cell region of the stacked structure and penetrating the stacked structure, and a first conductive contact and a second conductive contact in the extension region of the stacked structures and spaced apart from one another in the first direction. The first conductive contact penetrates a portion of the stacked structure and is connected to a first gate electrode. The second conductive contact penetrates another portion of the stacked structure and is connected to a second gate electrode. The first conductive contact includes a first contact portion penetrating the first gate electrode and spaced apart from the first gate electrode, and a second contact portion on the first gate electrode and connected to the first gate electrode.

### CROSS-REFERENCE TO RELATED APPLICATIONS

This present U.S. application claims priority to and the benefit under 35 U.S.C. § 119(a)-(d) of Korean Patent Application No. 10-2025-0057944, filed on May 2, 2025, in the Korean Intellectual Property Office, the entire disclosure of which is incorporated herein by reference.

### FIELD

The present disclosure relates to a three-dimensional semiconductor memory device and an electronic system including the same, and more particularly, to a three-dimension semiconductor memory device including conductive lines stacked in a vertical direction and an electronic system includes the same.

### BACKGROUND

There is a need for a semiconductor device capable of storing high-capacity data in an electronic system requiring data storage. There is a need to increase a degree of integration of semiconductor devices in order to meet the high performance and low cost required by consumers, while increasing data storage capacity. In the case of a two-dimensional or planar semiconductor device, since the degree of integration is mainly determined by the area occupied by the unit memory cell, the level of fine pattern formation technology is greatly affected. However, an increase in the degree of integration of a two-dimensional semiconductor device is limited because ultra-expensive equipment is required for miniaturization of a pattern.

### SUMMARY

Embodiments of the disclosed concepts provides a three-dimensional semiconductor memory device that is easily highly integrated and an electronic system including the same.

The problem to be solved by the present disclosure is not limited to the above-mentioned problem, and other problems not mentioned will be clearly understood by a person skilled in the art from the following description.

According to embodiments of the disclosed concepts, a three-dimensional semiconductor memory device may include a stacked structure including insulating layers and gate electrodes alternately stacked along a first direction, the stacked structure including a cell region and an extension region extending from the cell region in a second direction substantially perpendicular to the first direction, a vertical structure disposed in the cell region of the stacked structure and penetrating through the stacked structure along the first direction, and a first conductive contact and a second conductive contact which are disposed in the extension region of the stacked structures and are spaced apart from one another in the first direction. The first conductive contact may penetrate a portion of the stacked structure along the first direction and be connected to a first gate electrode of the gate electrodes. The second conductive contact may penetrate another portion of the stacked structure along the first direction and be connected to a second gate electrode of the gate electrodes stacked structure. The first conductive contact may include a first contact portion penetrating the first gate electrode along the first direction and spaced apart from the first gate electrode, and a second contact portion disposed on a surface of the first gate electrode and connected to the surface of the second gate electrode. A width in the second direction of the second contact portion may be greater than a width in the second direction of the first contact portion.

According to embodiments of the disclosed concepts, a three-dimensional semiconductor memory device may include a stacked structure including insulating layers and gate electrodes alternately stacked along a first direction, the stacked structure having a front surface and a rear surface opposite to one another in the first direction, a first conductive contact extending from the front surface of the stacked structure into the stacked structure, penetrating a portion of the stacked structure along the first direction, and connected to a first gate electrode of the gate electrodes, side insulating patterns interposed between the first conductive contact and the stacked structure and between the insulating layers and spaced apart from one another in the first direction, a second conductive contact extending from the rear surface of the stacked structures into the stacked structure, penetrating another portion of the stacked structures along the first direction and connected to a second gate electrode of the gate electrodes, and a side insulating spacer interposed between the second conductive contact and the stacked structure and extending in the first direction.

According to embodiments of the disclosed concepts, a three-dimensional semiconductor memory device may include a stacked structure including gate electrodes spaced apart from one another in a first direction and extending substantially parallel to one another in a second direction substantially perpendicular to the first direction, the stacked structure having a front surface and a rear surface opposite to one another in the first direction, a first conductive contact extending from the front surface of the stacked structure into the stacked structure, extending along the first direction to penetrate corresponding gate electrodes of the gate electrodes, and connected to a first gate electrode of the gate electrodes, side insulating patterns interposed between the first conductive contact and the corresponding gate electrodes, and spaced apart from one another in the first direction, a second conductive contact extending from the rear surface of the stacked structures into the stacked structure, extending along the first directions to penetrate other corresponding gate electrodes of the gate electrodes, and connected to a second gate electrode of the gate electrodes, and a side insulating spacer extending in the first direction between the second conductive contact and the other corresponding gate electrodes.

### BRIEF DESCRIPTION OF THE DRAWINGS

FIG. 1 is a diagram schematically illustrating an electronic system including a three-dimensional semiconductor memory device according to some embodiments of the disclosed concepts.

FIG. 2 is a perspective view schematically illustrating an electronic system including a three-dimensional semiconductor memory device according to some embodiments of the disclosed concepts.

FIGS. 3 and 4 are sectional views, each of which is taken along a line I-I′ of FIG. 2 to illustrate a semiconductor package including a three-dimensional semiconductor memory device according to some embodiments of the disclosed concepts.

FIG. 5 is a plan view for illustrating a three-dimensional semiconductor memory device according to some embodiments of the disclosed concepts.

FIG. 6 is a cross-sectional view taken along a line A-A′ of FIG. 5.

FIG. 7 is a cross-sectional view taken along a line B-B′ of FIG. 5.

FIG. 8 is a cross-sectional view taken along a line C-C′ of FIG. 5.

FIGS. 9 to 33 are cross-sectional views for illustrating a method of manufacturing a three-dimensional semiconductor memory device according to some embodiments of the disclosed concepts.

FIG. 34 is a cross-sectional view corresponding to the line C-C′ of FIG. 5 for illustrating a three-dimensional semiconductor memory device according to some embodiments of the disclosed concepts.

FIGS. 35 and 36 are cross-sectional views corresponding to the line B-B′ and the line C-C′ of FIG. 5, respectively, for illustrating a three-dimensional semiconductor memory device according to some embodiments of the disclosed concepts.

FIGS. 37 and 38 are cross-sectional views corresponding to the line B-B′ and the line C-C′ of FIG. 5, respectively, for illustrating a three-dimensional semiconductor memory device according to some embodiments of the disclosed concepts.

FIG. 39 is a cross-sectional view corresponding to the line C-C′ of FIG. 5 for illustrating a three-dimensional semiconductor memory device according to some embodiments of the disclosed concepts.

FIGS. 40 to 42 are cross-sectional views corresponding to the line A-A′, the line B-B′, and the line C-C′ of FIG. 5, respectively, for illustrating a three-dimensional semiconductor memory device according to some embodiments of the disclosed concepts.

FIG. 43 is a cross-sectional view corresponding to the line C-C′ of FIG. 5 for illustrating a three-dimensional semiconductor memory device according to some embodiments of the disclosed concepts.

FIG. 44 is a plan view for illustrating a three-dimensional semiconductor memory device according to some embodiments of the disclosed concepts.

FIG. 45 is a cross-sectional view taken along a line D-D′ of FIG. 44.

### DETAILED DESCRIPTION

Three-dimensional semiconductor memory devices having three-dimensionally arranged memory cells have been proposed. A three-dimensional semiconductor memory device may include memory cells stacked in a vertical direction, conductive lines respectively connected to the memory cells and stacked in the vertical direction, and conductive contacts respectively connected to the conductive lines.

Example embodiments of the disclosed concepts will now be described more fully with reference to the accompanying drawings, in which example embodiments are shown.

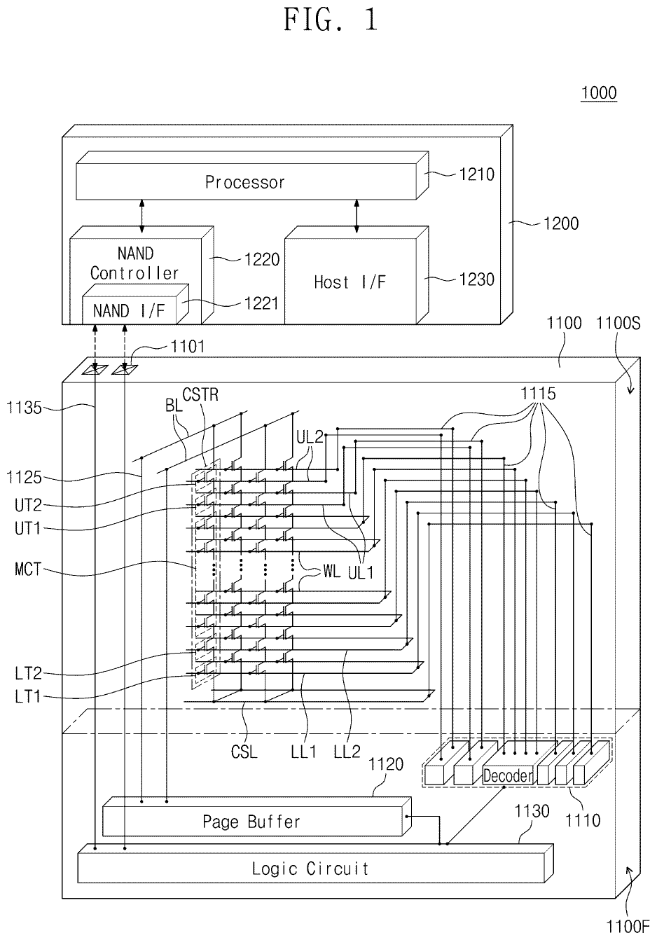

FIG. 1 is a diagram schematically illustrating an electronic system including a three-dimensional semiconductor memory device according to some embodiments of the disclosed concepts.

Referring to FIG. 1, an electronic system 1000 according to embodiments of the disclosed concepts may include a three-dimensional semiconductor memory device 1100 and a controller 1200, which is electrically connected to the three-dimensional semiconductor memory device 1100. The electronic system 1000 may be a storage device including one or a plurality of three-dimensional semiconductor memory devices 1100, or an electronic device including the storage device. As an example, the electronic system 1000 may be a solid state drive device (SSD device), a universal serial bus (USB), a computing system, a medical device, or a communication device, in which the three-dimensional semiconductor memory device 1100 is provided.

The three-dimensional semiconductor memory device 1100 may be a non-volatile memory device, and may be, for example, a three-dimensional NAND flash memory device as described below. The three-dimensional semiconductor memory device 1100 may include a first region 1100F and a second region 1100S on the first region 1100 F. According to some embodiments, unlike shown, the first region 1100F may be disposed next to the second region 1100S, or the first region 1100F may be disposed on the second region 1100S. The first region 1100F may be a peripheral circuit region including a decoder circuit 1110, a page buffer 1120, and a logic circuit 1130. The second region 1100S may be a memory cell region including a bit line BL, a common source line CSL, word lines WL, first lines LL1 and LL2, second lines UL1 and UL2, and memory cell strings CSTR between the bit line BL and the common source line CLS.

In the second region 1100S, each memory cell string CSTR may include first transistors LT1 and LT2 adjacent to the common source line CSL, second transistors UT1 and UT2 adjacent to the bit line BL, and a plurality of memory cell transistors MCT disposed between the first transistors LT1 and LT2 and the second transistors UT1 and UT2. The number of the first transistors LT1 and LT2 and the number of the second transistors UT1 and UT2 may be variously modified according to embodiments.

In an example, the first transistors LT1 and LT2 may include a ground selection transistor, and the second transistors UT1 and UT2 may include a string selection transistor. The first lines LL1 and LL2 may be gate electrodes of the first transistors LT1 and LT2, respectively. The word lines WL may be gate electrodes of the memory cell transistors MCT. The second lines UL1 and UL2 may be gate electrodes of the second transistors UT1 and UT2, respectively.

As an example, the first transistors LT1 and LT2 may include a first erase control transistor LT1 and a ground selection transistor LT2 connected in series. The second transistors UT1 and UT2 may include a string selection transistor UT1 and a second erase control transistor UT2 connected in series. At least one of the first erase control transistor LT1 or the second erase control transistor UT2 may be used for an erase operation of deleting data stored in the memory cell transistors MCT by using a gate induced leakage current (GIDL) phenomenon.

The common source line CSL, the first lines LL1 and LL2, the word lines WL, and the second lines UL1 and UL2 may be electrically connected to the decoder circuit 1110 through first connection lines 1115 extending from the first region 1100F to the second region 1100S. The bit line BL may be electrically connected to the page buffer 1120 through second connection lines 1125 extending from the first region 1100F to the second region 1100S.

In the first region 1100F, the decoder circuit 1110 and the page buffer 1120 may execute a control operation on at least one selected memory cell transistor among the plurality of memory cell transistors MCT. The decoder circuit 1110 and the page buffer 1120 may be controlled by the logic circuit 1130. The three-dimensional semiconductor memory device 1100 may communicate with the controller 1200 through an input/output pad 1101 electrically connected to the logic circuit 1130. The input/output pad 1101 may be electrically connected to the logic circuit 1130 through an input/output connection line 1135 extending from the first region 1100F to the second region 1100S.

The controller 1200 may include a processor 1210, a NAND controller 1220, and a host interface 1230. As an example, the electronic system 1000 may include a plurality of three-dimensional semiconductor memory devices 1100, and in this case, the controller 1200 may control the plurality of three-dimension semiconductor memory devices 1100.

The processor 1210 may control overall operations of the electronic system 1000 including the controller 1200. The processor 1210 may operate according to predetermined firmware, and may control the NAND controller 1220 to access the three-dimensional semiconductor memory device 1100. The NAND controller 1220 may include a NAND interface 1221 that processes communication with the three-dimensional semiconductor memory device 1100. Through the NAND interface 1221, a control command for controlling the three-dimensional semiconductor memory device 1100, data to be written to the memory cell transistors MCT of the three-dimensional semiconductor memory device 1100, and data to be read from the memory cells transistors MCT in the three-dimensional semiconductor memory device 1100 may be transmitted. The host interface 1230 may provide a communication function between the electronic system 1000 and an external host. Upon receiving a control command from an external host via the host interface 1230, the processor 1210 may control the three-dimensional semiconductor memory device 1100 in response to the control command.

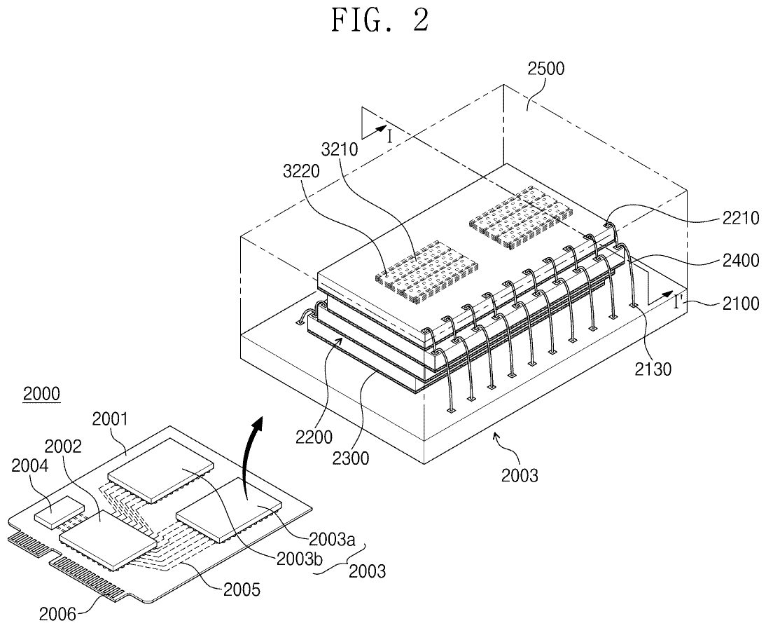

FIG. 2 is a perspective view schematically illustrating an electronic system including a three-dimensional semiconductor memory device according to some embodiments of the disclosed concepts.

Referring to FIG. 2, an electronic system 2000 according to embodiments of the disclosed concepts may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 through interconnection patterns 2005, which are provided on the main substrate 2001.

The main substrate 2001 may include a connector 2006 including a plurality of pins coupled with an external host. The number and placement of the plurality of pins of the connector 2006 may vary depending on the communication interface between the electronic system 2000 and the external host. For example, the electronic system 2000 may communicate with the external host according to any one of interfaces, such as Universal Serial Bus (USB), Peripheral Component Interconnect Express (PCI-Express), Serial Advanced Technology Attachment (SATA), and universal flash storage (UFS) M-PHY, or the like. In one example, the electronic system 2000 may be operated by a power source supplied from the external host via the connector 2006. The electronic system 2000 may further include a power management integrated circuit (PMIC) that distributes power supplied from the external host to the controller 2002 and the semiconductor package 2003.

The controller 2002 may write data to the semiconductor package 2003 or read data from the semiconductor package 2003, and may improve the operation speed of the electronic system 2000.

The DRAM 2004 may be a buffer memory for mitigating a speed difference between the semiconductor package 2003, which is a data storage device, and the external host. The DRAM 2004 included in the electronic system 2000 may also operate as a kind of cache memory and may provide a storage space for temporarily storing data in a control operation for the semiconductor package 2003. When the electronic system 2000 includes the DRAM 2004, the controller 2002 may further include a DRAM controller for controlling the DRAM 2004 in addition to a NAND controller for controlling the semiconductor package 2003.

The semiconductor package 2003 may include a first semiconductor package 2003a and a second semiconductor packages 2003b spaced apart from one another. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on a lower surface of each of the semiconductor chips 2300, a connection structure 2400 that electrically connects the semiconductor chips 2200 and the package substrate 2100, and a molding layer 2500 that covers the semiconductor chips 2200 and the connection structure 2400 on the package substrate 2100.

The package substrate 2100 may be a printed circuit board including package upper pads 2130. Each of the semiconductor chips 2200 may include input/output pads 2210. Each of the input/output pads 2210 may correspond to the input/output pad 1101 of FIG. 1. Each of the semiconductor chips 2200 may include gate stacked structures 3210 and vertical channel structures 3220. Each of the semiconductor chips 2200 may include a three-dimensional semiconductor memory device as described below.

As an example, the connection structure 2400 may be a bonding wire that electrically connects the input/output pads 2210 and the package upper pads 2130. In each of the first and second semiconductor packages 2003a and 2003b, the semiconductor chips 2200 may be electrically connected to one another in a bonding wire manner, and may be electrically connected to the package upper pads 2130 of the package substrate 2100. According to some embodiments, in each of the first and second semiconductor packages 2003a and 2003b, the semiconductor chips 2200 may be electrically connected to one another by a through-electrode (Through Silicon Via, TSV) instead of the connection structure 2400 provided in the form of the bonding wire manner.

As an example, the controller 2002 and the semiconductor chips 2200 may be included in one package. As an example, the controller 2002 and the semiconductor chips 2200 may be mounted on an interposer substrate different from the main substrate 2001, and the controller 2002 and the semiconductor chips 2200 are connected to one another through interconnection lines, which are provided in the interposer substrate.

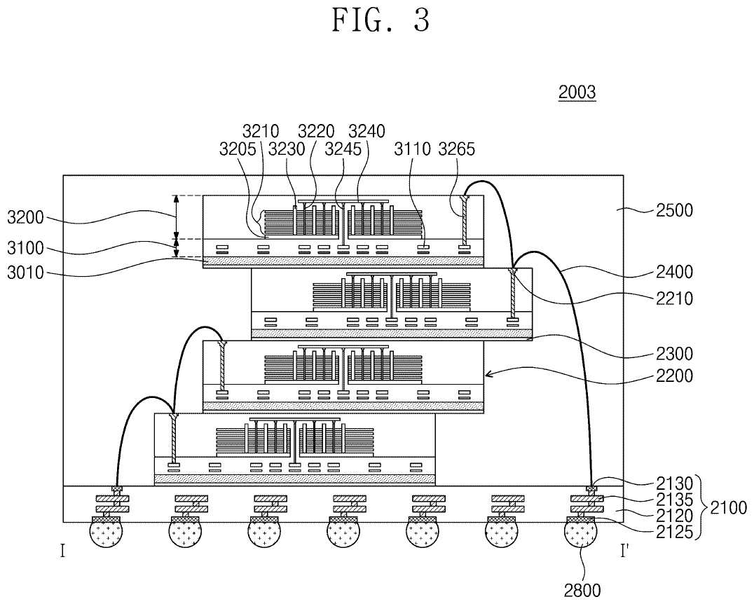

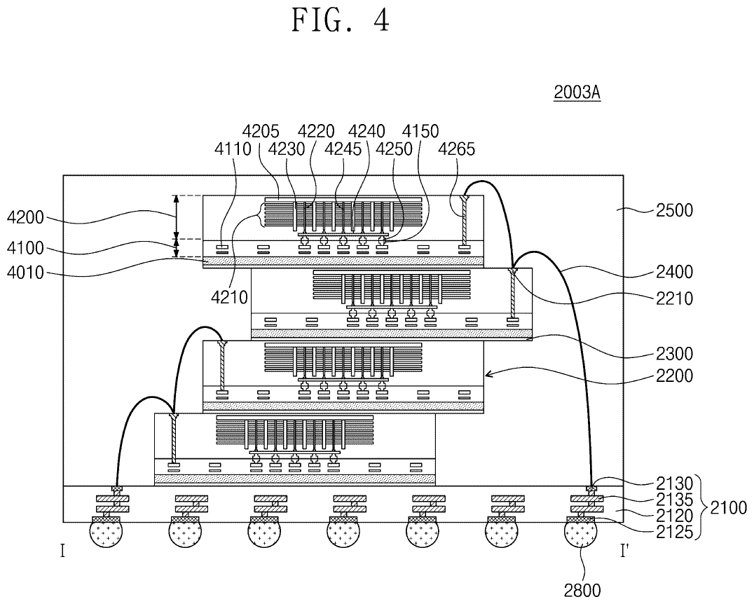

FIGS. 3 and 4 are sectional views, each of which is taken along a line I-I′ of FIG. 2 to illustrate a semiconductor package including a three-dimensional semiconductor memory device according to some embodiments of the disclosed concepts.

Referring to FIGS. 3 and 4, a semiconductor package 2003 and 2003A may include a package substrate 2100 and a plurality of semiconductor chips 2200 on the package substrate 2100, and a molding layer 2500 covering the package substrate 2100 and the plurality of semiconductor chips 2200.

The package substrate 2100 may include a package substrate body portion 2120, upper pads 2130 disposed on an upper surface of the package substrate body portion 2120, lower pads 2125 disposed on or exposed through a lower surface of the package board body portion 2120, and internal wirings 2135 electrically connecting the upper pads 2130 and the lower pads 2125 inside the package substrate body portions 2120. The upper pads 2130 may be electrically connected with the connection structures 2400. The lower pads 2125 may be connected to the interconnection patterns 2005 of the main substrate 2010 of the electronic system 2000 shown in FIG. 2 via conductive connections 2800.

Referring to FIG. 3, according to some embodiments, each of the semiconductor chips 2200 of the semiconductor package 2003 may include a semiconductor substrate 3010, and a first structure 3100 and a second structure 3200 which are sequentially stacked on the semiconductor substrate 3010. The first structure 3100 may correspond to the peripheral circuit structure (the first region 1100F in FIG. 1) in the above-described embodiments, and the second structure 3200 may correspond to the cell array structure (the second region 1100S in FIG. 1) in the above-mentioned embodiments.

The first structure 3100 may include a peripheral circuit region including peripheral wires 3110. The second structure 3200 may include a source structure 3205, a stacked structure 3210 on the source structure 3205, vertical structures 3220 and separation structures 3230 penetrating the stacked structure 3210, bit lines 3240 electrically connected with the vertical structures 3220, and cell contact plugs electrically connected with word lines (WL in FIG. 1) of the stacked structure 3210.

Each of the semiconductor chips 2200 may include a through wiring 3245 that is electrically connected to the peripheral wirings 3110 of the first structure 3100 and extends into the second structure 3200. The through wiring 3245 may be disposed outside the stacked structure 3210, and may be further disposed to penetrate the stacked structure 3210. Each of the semiconductor chips 2200 may further include an input/output pad 2210 (FIG. 2) electrically connected to the peripheral wirings 3110 of the first structure 3100.

Referring to FIG. 4, according to some embodiments, each of the semiconductor chips 2200 of the semiconductor package 2003A may include a semiconductor substrate 4010, a first structure 4100 on the semiconductor substrate 4010 and a second structure 4200 disposed on the first structure 4100 and bonded with the first structure 4100 in a wafer bonding manner. The first structure 4100 may correspond to a peripheral circuit structure in the embodiments described above, and the second structure 4200 may correspond to a cell array structure in the embodiments explained above.

The first structure 4100 may include a peripheral circuit region including peripheral wiring 4110 and first junction structures 4150. The second structure 4200 may include a source structure 4205, a stacked structure 4210 between the source structure 4205 and the first structure 4100, vertical structures 4220 and a separating structure 4230 penetrating the stacked structure 4210, and second bonding structures 4250 electrically connected with word lines (WL in FIG. 1) of the stacked structure 4210 and the vertical structures 4220, respectively. For example, the second junction structures 4250 may be electrically connected with the vertical structures 4220 through bit lines 4240 electrically connected with the vertical structures 4220, and may be electrically connected with the word lines (WL in FIG. 1) through cell contact plugs electrically connected with the word lines (WL in FIG. 1). The first bonding structures 4150 of the first structure 4100 and the second bonding structures 4250 of the second structure 4200 may be bonded by contacting one another. The bonded portions of the first bonding structures 4150 and the second bonding structures 4250 may be formed of, for example, copper (Cu). Each of the semiconductor chips 2200 may further include an input/output pad 2210 (FIG. 2) electrically connected to the peripheral wirings 4110 of the first structure 4100.

Referring again to FIGS. 3 and 4, the semiconductor chips 2200 may be electrically connected to one another by connection structures 2400 provided in the form of bonding wires. According to some embodiments, unlike shown, the semiconductor chips 2200 may be electrically connected to one another by a connection structure including a through electrode TSV.

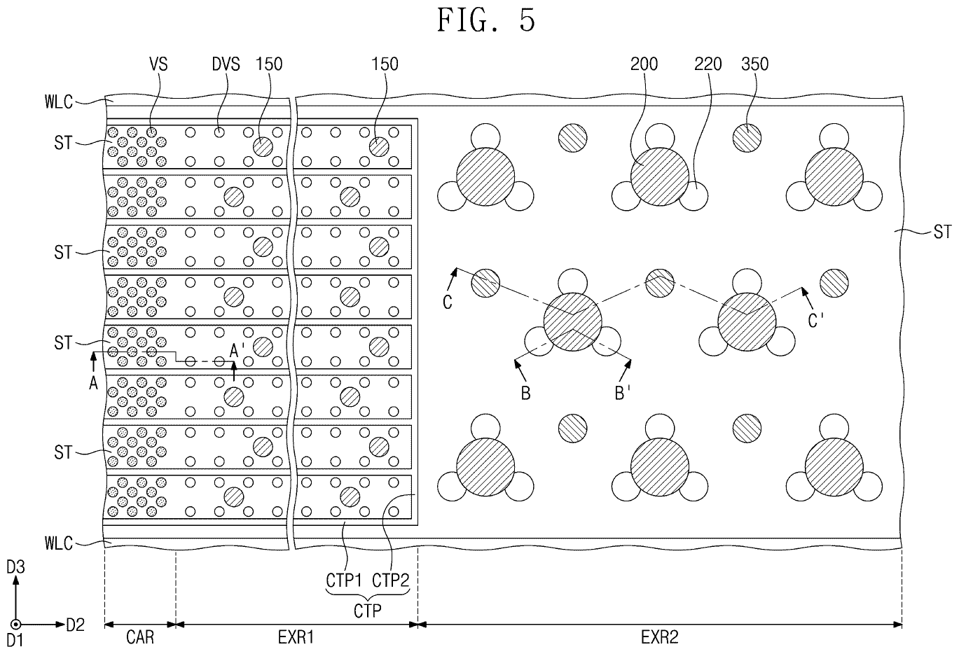

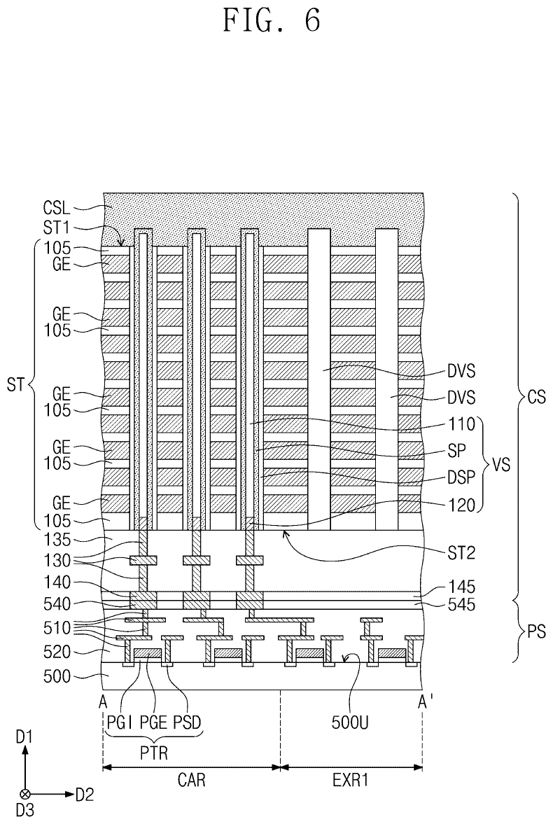

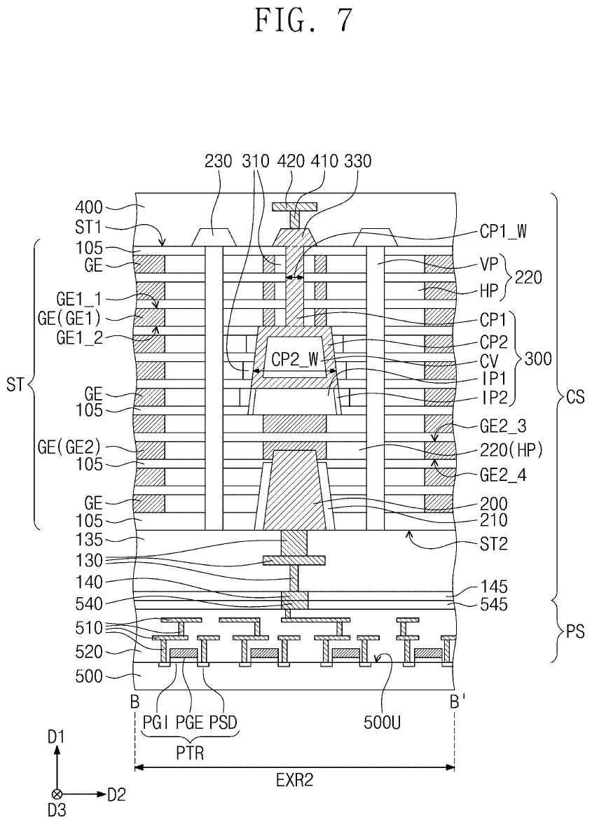

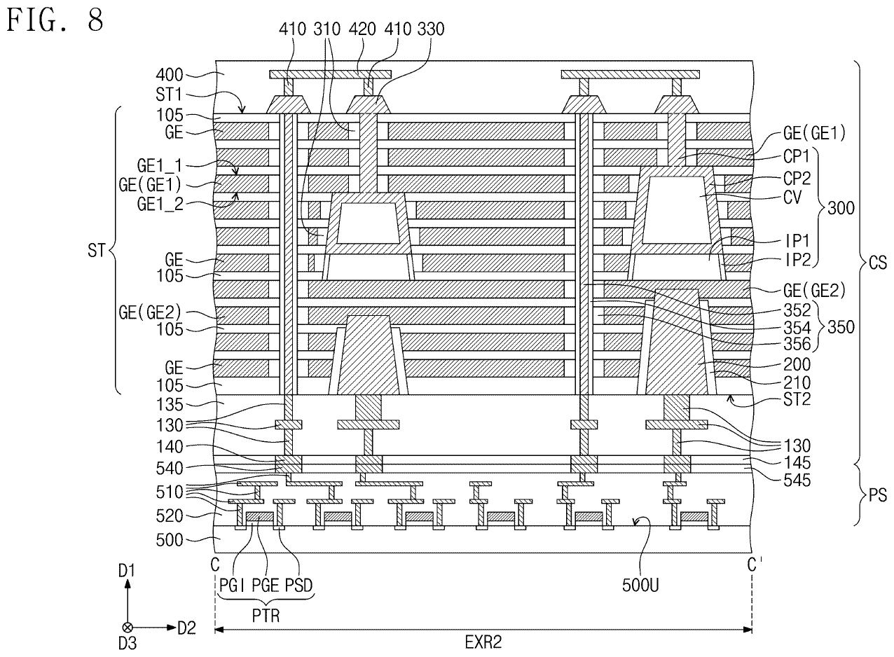

FIG. 5 is a plan view for illustrating a three-dimensional semiconductor memory device according to some embodiments of the disclosed concepts. FIG. 6 is a cross-sectional view taken along a line A-A′ of FIG. 5, FIG. 7 is a cross-sectional view taken along a line B-B′ of FIG. 5, and FIG. 8 is a cross-sectional view taken along a line C-C′ of FIG. 5.

Referring to FIGS. 5 to 8, a three-dimensional semiconductor memory device may include a semiconductor substrate 500, a peripheral circuit structure PS, and a cell array structure CS. The peripheral circuit structure PS and the cell array structure CS may be sequentially stacked on the semiconductor substrate 500 along a first direction D1, and the peripheral circuit structure PS may be disposed between the semiconductor substrate 500 and the cell array structures CS. The first direction D1 may be perpendicular to an upper surface 500U of the semiconductor substrate 500. The semiconductor substrate 500, the peripheral circuit structure PS, and the cell array structure CS may correspond to the semiconductor substrates 3010 and 4010, the first structures 3100 and 4100, and the second structures 3200 and 4200 described with reference to FIGS. 3 and 4, respectively.

The semiconductor substrate 500 may be, for example, a silicon substrate, a silicon-Attorney germanium substrate, a germanium substrate, or a monocrystalline epitaxial layer grown from a monocrystalline silicon substrate.

The peripheral circuit structure PS may be disposed on the semiconductor substrate 500. The peripheral circuit structure PS may correspond to the first region 1100F of FIG. 1. The peripheral circuit structure PS may include peripheral transistors PTR on the semiconductor substrate 500, peripheral wirings 510 electrically connected to the peripheral transistors PTR, a peripheral insulating layer 520 covering the peripheral transistors PTR and the peripheral wirings 510, peripheral bonding pads 540 connected to the peripheral wirings 510, and a peripheral bonding insulating layer 545 covering the peripheral bonding pads 540.

Each of the peripheral transistors PTR may include a peripheral gate insulating layer PGI, a peripheral gate electrode PGE, and peripheral source/drain regions PSD. The peripheral gate insulating layer PGI may be interposed between the semiconductor substrate 500 and the peripheral gate electrode PGE, and the peripheral source/drain regions PSD may be disposed in the semiconductor substrate 500 at both sides of the peripheral gate electrode PGE. The peripheral transistors PTR may be NMOS transistors or PMOS transistors, and may be fin field effect transistors FinFET, multi-bridge channel transistors MBCFET, or gate-all-around transistors.

The peripheral wirings 510 may be electrically connected to the peripheral transistors PTR. The peripheral wirings 510 may include a conductive material such as a metal. The peripheral transistors PTR and the peripheral wirings 510 may constitute a peripheral circuit (for example, the decoder circuit 1110, the page buffer 1120, the logic circuit 1130, and the like in FIG. 1). The peripheral insulating layer 520 may include a plurality of insulating layers having a multilayer structure. As an example, the peripheral insulating layer 520 may include an insulating material such as silicon oxide, silicon nitride, silicon oxynitride, and/or a low dielectric material.

The peripheral bonding pads 540 may be disposed on the peripheral insulating layer 520 and may be spaced apart from one another in a second direction D2 parallel to the upper surface 500U of the semiconductor substrate 500. The peripheral bonding pads 540 may be electrically connected to the peripheral wirings 510, and may include a conductive material such as a metal. The peripheral bonding insulating layer 545 may be disposed on the peripheral insulating layer 520 and may extend between the peripheral bonding pads 540. The peripheral bonding insulating layer 545 may cover side surfaces of the peripheral bonding pads 540 and may expose top surfaces of the peripheral bond pads 540. The peripheral bonding insulating layer 545 may include, for example, an insulating material such as silicon oxide, silicon nitride, silicon oxynitride, and/or a low dielectric material. The peripheral bonding pads 540 may correspond to the first bonding structures 4150 of FIG. 4.

The cell array structure CS may be disposed on the peripheral circuit structure PS. The cell array structure CS may correspond to the second region 1100S of FIG. 1. The cell array structure CS may include a stacked structure ST including insulating layers 105 and gate electrodes GE alternately stacked along the first direction D1. The stacked structure ST may extend in the second direction D2 and a third direction D3. The second direction D2 and the third direction D3 may be parallel to the upper surface 500U of the semiconductor substrate 500 and may intersect with one another. The first direction D1 may be perpendicular to both the second direction D2 and the third direction D3. The first direction D1 may be referred to as a vertical direction, and the second direction D2 and the third direction D3 may be referred to respectively as a horizontal direction.

The stacked structure ST may include a cell region CAR, a first extension region EXR 1 extending from the cell region CAR in the second direction D2, and a second extension region EXR2 extending from the first extension region EX R1 in the second directionD2. The insulating layers 105 and the gate electrodes GE of the stacked structure ST may extend parallel to one another along the second direction D2 in the cell region CAR, the first extension region EXR1, and the second extension region EXR2.

The stacked structure ST may have a front surface ST1 and a rear surface ST2 opposite to one another in the first direction D1. The stacked structure ST may be disposed such that the rear surface ST2 of the stacked structure ST faces the peripheral circuit structure PS. A height of the front surface ST1 of the first extension region EXR1 and the second extension region EXR2 of the stacked structure ST may be the same as a height of the front surface ST1 of the cell region CAR of the stacked structure ST. A height of the rear surface ST2 of the first extension region EXR1 and the second extension region EXR2 of the stacked structure ST may be the same as a height of the rear surface ST2 of the cell region CAR of the stacked structure ST. Here, the height is a distance measured in the first direction D1 from the upper surface 500U of the semiconductor substrate 500. That is, the cell region CAR, the first extension region EXR1, and the second extension region EXR2 of the stacked structure ST may not have a stepped structure. The second direction D2 and the third direction D3 may be parallel to the front surface ST1 and the rear surface ST2 of the stacked structure ST.

The insulating layers 105 may include a silicon oxide layer and/or a low dielectric layer. The gate electrodes GE may include, for example, at least one selected from a doped semiconductor (ex, doped silicon, etc.), a metal (ex, tungsten, copper, aluminum, etc.), a conductive metal nitride (ex, titanium nitride, tantalum nitride, etc.), or a transition metal (ex, titanium, tantalum, etc.). According to some embodiments, the three-dimensional semiconductor memory device may be a vertical NAND flash memory device, and the gate electrodes GE of the stacked structure ST may constitute the word lines WL, the first lines LL1 and LL2, and the second lines UL1 and UL2 of FIG. 1.

The cell array structure CS may further include separation structures WLC, first cutting patterns CTP1, and a second cutting pattern CTP2. The separation structures WLC may be spaced apart from one another in the third direction D3 with the stacked structure ST interposed therebetween, and may extend in the second direction D2 along the cell region CAR and the first and second extension regions EXR1 and EXR2 of the stacked structure ST. The separation structures WLC may cover side surfaces of the stacked structure ST, which are opposite to one another in the third direction D3, respectively. The first cutting patterns CTP1 may be disposed in the cell region CAR and the first extension region EXR1 of the stacked structure ST. The first cutting patterns CTP1 may be spaced apart from one another in the third direction D3 and may extend in the second direction D2, in the cell region CAR and the first extension region EXR1 of the stacked structure ST. The second cutting pattern CTP2 may be disposed in the first extension region EXR1 of the stacked structure ST and may extend in the third direction D3. In the first extension region EXR1 of the stacked structure ST, ends of the first cutting patterns CTP1 may be connected to the second cutting pattern CTP2. Each of the first and second cutting patterns CTP1 and CTP2 may be disposed adjacent to the rear surface ST2 of the stacked structure ST, and may penetrate a portion (for example, at least one insulating layer 105 and at least one gate electrode GE) of the stacked structure ST along the first direction D1. The second lines UL1 and UL2 of FIG. 1 may be defined by the first and second cutting patterns CTP1 and CTP2. The first and second cutting patterns CTP1 and CTP2 may include an insulating material such as silicon oxide, silicon nitride, silicon oxynitride, and/or a low dielectric material. The first and second cutting patterns CTP1 and CTP2 may be referred to as a cutting pattern CTP.

The cell array structure CS may further include a vertical structure VS disposed in the cell region CAR of the stacked structure ST. The vertical structure VS may penetrate the stacked structure ST along the first direction D1. The vertical structure VS may constitute the memory cell string CSTR of FIG. 1, and may constitute channels of the first transistors LT1 and LT2, the memory cell transistors MCT, and the second transistors UT1 and UT2 of FIG. 1. The vertical structure VS may be provided in plural. A plurality of vertical structures VS may be arranged to be spaced apart from one another along the second direction D2 and the third direction D3 between the first cutting patterns CTP1.

The vertical structure VS may include a vertical semiconductor pattern SP penetrating the stacked structure ST along the first direction D1, a data storage pattern DSP extending in the first direction D1 between the vertical semiconductor pattern SP and the stacked structure ST, an internal insulating pattern 110 disposed inside the vertical semiconductor pattern SP, and a conductive pad 120 on the internal insulating pattern 110. The vertical semiconductor pattern SP may be interposed between the internal insulating pattern 110 and the data storage pattern DSP, and may extend between the conductive pad 120 and the data storage patterns DSP.

The vertical semiconductor pattern SP may be in the form of a pipe with a closed bottom, and may include an impurity-doped semiconductor material, an intrinsic semiconductor material in an impurity undoped state, or a polycrystalline semiconductor material. The vertical semiconductor pattern SP may be used as channels of the upper transistors UT1 and UT2, the memory cell transistors MCT, and the lower transistors LT1 and LT2 of FIG. 1. The data storage pattern DSP may surround a side surface of the vertical semiconductor pattern SP between the vertical semiconductor pattern SP and the stacked structure ST. The data storage pattern DSP may be in the form of a pipe whose upper and lower ends are open. The data storage pattern DSP is a data storage layer of a NAND flash memory device, and may include a tunnel insulating layer, a charge storage layer, and a blocking insulating layer interposed between the vertical semiconductor pattern SP and the stacked structure ST. As an example, the charge storage layer may be a trap insulating layer, a floating gate electrode, or an insulating layer including conductive nano dots. The blocking insulating layer may be adjacent to a side surface of the stacked structure ST, and the tunnel insulating layer may be adjacent to the vertical semiconductor pattern SP. The charge storage layer may be interposed between the blocking insulating layer and the tunnel insulating layer.

The internal insulating pattern 110 may fill a space surrounded by the vertical semiconductor pattern SP. The internal insulating pattern 110 may include an insulating material such as silicon oxide. The conductive pad 120 may be electrically connected to the vertical semiconductor pattern SP, and may include a semiconductor material doped with impurities or a conductive material.

The cell array structure CS may further include a dummy vertical structure DVS and a contact plug 150 disposed in the first extension region EXR1 of the stacked structure ST. The dummy vertical structure DVS may penetrate the stacked structure ST along the first direction D1. The dummy vertical structure DVS may be provided in plural. A plurality of dummy vertical structure DVS may be arranged to be spaced apart from one another along the second direction D2 and the third direction D3 between the first cutting patterns CTP1. As an example, the dummy vertical structure DVS may include an insulating material such as silicon oxide, silicon nitride, silicon oxynitride, and/or a low dielectric material. In another example, the dummy vertical structure DVS may be formed at the same time as the vertical structure VS, and may have the same thin film structure as the vertical structure VS. According to some embodiments, the contact plug 150 may be disposed adjacent to the rear surface ST2 of the stacked structure ST. The contact plug 150 may be provided in plural. A plurality of contact plugs 150 may be arranged to be spaced apart from one another in the second direction D2 between the first cutting patterns CTP1. The contact plug 150 may penetrate a portion of the stacked structure ST along the first direction D1, and may be connected (e.g., electrically connected) to a corresponding one of the gate electrodes GE. The contact plug 150 may include a conductive material such as a metal.

The cell array structure CS may further include a first conductive contact 300 and a second conductive contact 200 disposed in the second extension region EXR2 of the stacked structure ST and spaced apart from one another in the first direction D1, side insulating patterns 310 on a side surface of the first conductive contact 300, and a side insulating spacer 210 on a side surface of the second conductive contact 200.

The first conductive contact 300 may be provided in plural and a plurality of first conductive contacts 300 may be spaced apart from one another in the second direction D2 and the third direction D3 in the second extension region EXR2 of the stacked structure ST. The second conductive contact 200 may be provided in plural and a plurality of second conductive contacts 200 may be spaced apart from one another in the second direction D2 and the third direction D3 in the second extension region EXR2 of the stacked structure ST. The plurality of first conductive contacts 300 may be spaced apart from the plurality of second conductive contacts 200 along the first direction D1. According to some embodiments, the first conductive contact 300 and the second conductive contact 200 may be aligned with one another along the first direction D1, and may vertically overlap one another along the first direction D1.

The first conductive contact 300 may extend from the front surface ST1 of the stacked structure ST into the stacked structure ST, and may penetrate a portion (for example, at least one insulating layer 105 and at least one gate electrode GE) of the stacked structure ST along the first direction D1. The first conductive contact 300 may be connected (e.g., electrically connected) to a first gate electrode GE1 of the gate electrodes GE. The first gate electrode GE1 may have a first surface GE1_1 and a second surface GE1_2 opposite to one another in the first direction D1. The first surface GE1_1 of the first gate electrode GE1 may face the front surface ST1 of the stacked structure ST, and the second surface GE1_2 of the first gate electrodes GE1 may face the rear surface ST2 of the stacked structure ST.

The first conductive contact 300 may include a first contact portion CP1 penetrating the first surface GE1_1 of the first gate electrode GE1 and the first gate electrode GE1, and a second contact portion CP2 disposed on the second surface GE1_2 of the first gate electrodes GE1 and connected (e.g., electrically connected) to the second surface gel_2 of the first gate electrodes GE1. The first contact portion CP1 may further penetrate a portion of the stacked structure ST (that is, corresponding gate electrodes GE and corresponding insulating layers 105) between the front surface ST1 of the stacked structure ST and the first surface GE1_1 of the first gate electrode GE1. The second contact portion CP2 may penetrate a portion of the stacked structure ST (i.e., corresponding gate electrodes GE and corresponding insulating layers 105) on the second surface GE1_2 of the first gate electrode GE1. A width CP2_W of the second contact portion CP2 in the second direction D2 may be greater than a width CP1_W of the first contact portion CP1 in the second directionD2. The first contact portion CP1 may be spaced apart from the first gate electrode GE1, and the second contact portion CP2 may be connected (e.g., electrically connected) to the second surface GE1_2 of the first gate electrode GE1. The first conductive contact 300 may be connected (e.g., electrically connected) to the first gate electrode GE1 through the second contact portion CP2 and the second surface GE1_2 of the first gate electrode GE1. The first contact portion CP1 and the second contact portion CP2 may include a conductive material such as a metal.

The first conductive contact 300 may further include a first insulating pattern IP1 and a second insulating pattern IP2 on the second contact portion CP2. The first insulating pattern IP1 may penetrate a portion (for example, corresponding insulating layers 105 and corresponding gate electrodes GE) of the stacked structure ST along the first direction D1, and the second insulating pattern IP2 may be interposed between the stacked structure ST and the first insulating pattern IP1. The second contact portion CP2 may be disposed between the first and second insulating patterns IP1 and IP2 and the first contact portion CP1. The first and second insulating patterns IP1, IP2 may include an insulating material such as silicon oxide, silicon nitride, silicon oxynitride, and/or a low dielectric material.

According to some embodiments, the first conductive contact 300 may further include a void CV in the second contact portion CP2. The void CV may be an empty region surrounded by the second contact portion CP2.

The side insulating patterns 310 may be disposed between the first conductive contact 300 and the stacked structure ST. The side insulating patterns 310 may be interposed between the first contact portion CP1 and the stacked structure ST, between the second contact portion CP2 and the stacked structure ST, and between the second insulating pattern IP2 and the stacked structures ST. The side insulating patterns 310 may be interposed between the insulating layers 105 and may be spaced apart from one another in the first direction D1. The side insulating patterns 310 may include an insulating material such as silicon oxide, silicon nitride, silicon oxynitride, and/or a low dielectric material.

The plurality of first conductive contacts 300 may be respectively connected (for example, electrically connected) to corresponding first gate electrodes GE1 among the gate electrodes GE. The corresponding first gate electrodes GE1 may be positioned at different heights along the first direction D1. According to some embodiments, the first insulating patterns IP1 of the plurality of first conductive contacts 300 may be positioned at the same height as one another along the first direction D1, and the second insulating patterns IP2 of the plurality of the first conductive contacts 300 may be positioned at a same height as one another along the first direction D1.

The second conductive contact 200 may extend from the rear surface ST2 of the stacked structure ST into the stacked structure ST, and may penetrate a portion (for example, at least one insulating layer 105 and at least one gate electrode GE) of the stacked structure ST along the first direction D1. The second conductive contact 200 may be connected (e.g., electrically connected) to a second gate electrode GE2 of the gate electrodes GE. The first gate electrode GE1 and the second gate electrode GE2 may be positioned at different heights along the first direction D1. The second gate electrode GE2 may have a third surface GE2_3 and a fourth surface GE2_4 opposite to one another in the first direction D1. The third surface GE2_3 of the second gate electrode GE2 may face the front surface ST1 of the stacked structure ST, and the fourth surface GE2_4 of the second gate electrodes GE2 may face the rear surface ST2 of the stacked structure ST. The second conductive contact 200 may extend into the second gate electrode GE2 through the fourth surface GE2_4 of the second gate electrode GE2, and may be spaced apart from the third surface GE2_3 of the second gate electrodes GE2. The second conductive contact 200 may include a conductive material such as a metal.

The side insulating spacer 210 may be interposed between the second conductive contact 200 and the stacked structure ST, and may extend in the first direction D1 along a side surface of the second conductive contact 200. The side insulating spacer 210 may penetrate a portion (for example, at least one insulating layer 105 and at least one gate electrode GE) of the stacked structure ST along the first direction D1. The side insulating spacer 210 may include an insulating material such as silicon oxide, silicon nitride, silicon oxynitride, and/or a low dielectric material.

The plurality of second conductive contacts 200 may be respectively connected (e.g., electrically connected) to corresponding second gate electrodes GE2 among the gate electrodes GE. The corresponding second gate electrodes GE2 may be positioned at different heights along the first direction D1.

The cell array structure CS may further include support structures 220 disposed in the second extension region EXR2 of the stacked structure ST. The support structures 220 may be spaced apart from one another in the second direction D2 and the third direction D3 in the second extension region EXR2 of the stacked structure ST. Each of the support structures 220 may penetrate the stacked structure ST along the first direction D1. According to some embodiments, the first conductive contact 300 and the second conductive contact 200 may be disposed between at least three support structures 220 that are adjacent to one another. According to some embodiments, each of the support structures 220 may include a vertical portion VP penetrating the stacked structure ST along the first direction D1, and horizontal portions HP extending from the vertical portion VP between the insulating layers 105. The horizontal portions HP may be spaced apart from one another in the first direction D1, and the horizontal portions HP and the insulating layers 105 may be alternately stacked along the first direction D1. The vertical portion VP and the horizontal portions HP may include an insulating material such as silicon oxide, silicon nitride, silicon oxynitride, and/or a low dielectric material.

The cell array structure CS may further include a through electrode structure 350 disposed in the second extension region EXR2 of the stacked structure ST. The through electrode structure 350 may be provided in plural, and a plurality of through electrode structures 350 may be spaced apart from one another in the second direction D2 and the third direction D3 in the second extension region EXR2 of the stacked structure ST. The through-electrode structure 350 may include a vertical electrode pattern 352 penetrating the stacked structure ST along the first direction D1, a vertical insulating pattern 354 interposed between the vertical electrode pattern 352 and the stacked structure ST and penetrating the stacked structure ST along the first direction D1, and horizontal insulating patterns 356 extending from the vertical insulating pattern 354 between the insulating layers 105. The horizontal insulating patterns 356 may be spaced apart from one another in the first direction D1, and the horizontal insulating patterns 356 and the insulating layers 105 may be alternately stacked along the first direction D1. The vertical electrode pattern 352 may include a conductive material such as a metal, and the vertical insulating pattern 354 and the horizontal insulating patterns 356 may include an insulating material such as silicon oxide, silicon nitride, silicon oxynitride, and/or a low dielectric material.

The cell array structure CS may further include a source pattern CSL disposed on the front surface ST1 of the stacked structure ST, buried conductive patterns 330, buried insulating patterns 230, first wiring patterns 410 and 420, and a first interlayer insulating layer 400.

The source pattern CSL may be disposed on the cell region CAR and the first extension region EXR1 of the stacked structure ST, and may extend in the second direction D2 and the third direction D3. The vertical semiconductor pattern SP of the vertical structure VS may extend into the source pattern CSL along the first direction D1 and may be connected (e.g., electrically connected) to the source pattern CLS. The dummy vertical structure DVS may extend into the source pattern CSL along the first direction D1. The dummy vertical structure DVS may be electrically isolated from the source pattern CSL. The source pattern CSL may include a conductive material, and may include, for example, a doped semiconductor material and/or an intrinsic semiconductor material. The source pattern CSL may constitute the common source line CSL of FIG. 1.

The buried conductive patterns 330 and the buried insulating patterns 230 may be disposed on the second extension region EXR2 of the stacked structure ST, and may be spaced apart from one another along the second direction D2 and the third direction D3. The buried conductive patterns 330 may be disposed on the first conductive contact 300 and the through electrode structure 350, respectively. The first contact portion CP1 of the first conductive contact 300 may be connected (for example, electrically connected) to a corresponding buried conductive pattern 330 among the buried conductive patterns 330. The vertical electrode pattern 352 of the through electrode structure 350 may be connected (e.g., electrically connected) to a corresponding buried conductive pattern 330 of the buried conductive patterns 330. The buried insulating patterns 230 may be disposed on the support structures 220, respectively. The vertical portion VP of each of the support structures 220 may be in contact with a corresponding one of the buried insulating patterns 230. The buried conductive patterns 330 may include a conductive material such as a metal, and the buried insulating patterns 230 may include an insulating material such as silicon oxide, silicon nitride, silicon oxynitride, and/or a low dielectric material.

The first wiring patterns 410 and 420 may be disposed on the second extension region EXR2 of the stacked structure ST. The first wiring patterns 410 and 420 may include first wiring contacts 410 connected (e.g., electrically connected) to the buried conductive patterns 330, and first wiring lines 420 connected to the first wiring contacts 410. The first wiring patterns 410 and 420 may include a conductive material such as a metal. The first conductive contact 300 may be electrically connected to the through electrode structure 350 through the buried conductive patterns 330 and the first wiring patterns 410 and 420.

The first interlayer insulating layer 400 may be disposed on the second extension region EXR2 of the stacked structure ST, and may cover the buried conductive patterns 330, the buried insulating patterns 230, and the first wiring patterns 410 and 420. The first interlayer insulating layer 400 may include an insulating material such as silicon oxide, silicon nitride, silicon oxynitride, and/or a low dielectric material.

The cell array structure CS may further include second wiring patterns 130, a second interlayer insulating layer 135, cell bonding pads 140, and a cell bonding insulating layer 145, which are disposed on the rear surface ST2 of the stacked structure ST. The second wiring patterns 130, the second interlayer insulating layer 135, the cell bonding pads 140, and the cell bonding insulating layer 145 may be disposed between the rear surface ST2 of the stacked structure ST and the peripheral circuit structure PS.

The second wiring patterns 130 may be disposed on the cell region CAR, the first extension region EXR1, and the second extension region EXR2 of the stacked structure ST. The conductive pad 120 of the vertical structure VS may be connected (for example, electrically connected) to corresponding second wiring patterns 130 among the second wiring patterns 130. The second conductive contact 200 may be connected (for example, electrically connected) to corresponding second wiring patterns 130 among the second wiring patterns 130. The vertical electrode pattern 352 of the through electrode structure 350 may be connected (e.g., electrically connected) to corresponding second wiring patterns 130 of the second wiring patterns 130. The second wiring patterns 130 may include a conductive material such as a metal.

The second interlayer insulating layer 135 may be disposed on the cell region CAR, the first extension region EXR1, and the second extension region EXR2 of the stacked structure ST, and may cover the second wiring patterns 130. The second interlayer insulating layer 135 may include an insulating material such as silicon oxide, silicon nitride, silicon oxynitride, and/or a low dielectric material.

The cell bonding pads 140 may be disposed on the cell region CAR, the first extension region EXR1, and the second extension region EXR2 of the stacked structure ST, and may be disposed on the second interlayer insulating layer 135. The cell bonding pads 140 may be spaced apart from one another in the second direction D2. Each of the cell bonding pads 140 may be connected (e.g., electrically connected) to a corresponding one of the second wiring patterns 130. The cell bonding insulating layer 145 may be disposed on the cell region CAR, the first extension region EXR1, and the second extension region EXR2 of the stacked structure ST, and may be disposed on the second interlayer insulating layer 135. The cell bonding insulating layer 145 may extend between the cell bonding pads 140 and may cover side surfaces of the cell bonding pad 140. The cell bonding insulating layer 145 may expose top surfaces of the cell bonding pads 140. The cell bonding pads 140 may include a conductive material such as a metal, and the cell bonding insulating layer 145 may include, for example, an insulating material such as silicon oxide, silicon nitride, silicon oxynitride, and/or a low dielectric material. The cell bonding pads 140 may correspond to the second bonding structures 4250 of FIG. 4.

The cell bonding pads 140 may be in contact with the peripheral bonding pads 540 and may be connected (e.g., electrically connected) to the peripheral bonding pads 540, respectively. The cell bonding insulating layer 145 may be in contact with the peripheral bonding insulating layer 545. The cell structure CS and the peripheral circuit structure PS may be bonded to one another by the cell bonding pads 140, the peripheral bonding pads 540, the cell bonding insulating layer 145, and the peripheral bonding insulating layer 545.

The vertical structure VS may be electrically connected to the peripheral circuit structure PS through the second wiring patterns 130, the cell bonding pads 140, and the peripheral bonding pads 540. The first gate electrode GE1 of the gate electrodes GE of the stacked structure ST may be electrically connected to the peripheral circuit structure PS through the first conductive contact 300, the buried conductive patterns 330, the first wiring patterns 410 and 420, the through electrode structure 350, the second wiring patterns 130, the cell bonding pads 140, and the peripheral bonding pads 540. The second gate electrode GE2 of the gate electrodes GE of the stacked structure ST may be electrically connected to the peripheral circuit structure PS through the second conductive contact 200, the second wiring patterns 130, the cell bonding pads 140, and the peripheral bonding pads 540.

When the number of the gate electrodes GE of the stacked structure ST is increased, the number of conductive contacts connected (e.g., electrically connected) to the gate electrodes GE may also be increased. In this case, an increase in an area of the second extension region EXR2 of the stacked structure ST may be required for the arrangement of the conductive contacts.

According to embodiments of the disclosed concepts, the first conductive contact 300 and the second conductive contact 200 may be disposed to be spaced apart from one another in the first direction D1 in the second extension region EXR2 of the stacked structure ST, and may be respectively connected (for example, electrically connected) to the first gate electrode GE1 and the second gate electrode GE2, which are located at different heights. Some of the gate electrodes GE of the stacked structure ST may be respectively connected (e.g., electrically connected) to the plurality of first conductive contacts 300, and the rest of the gate electrodes GE of the stacked structure ST may be respectively connected to the plurality of second conductive contacts 200. In the second extension region EXR2 of the stacked structure ST, the plurality of first conductive contacts 300 may be vertically spaced apart from the plurality of second conductive contacts 200 along the first direction D1. In this case, the first and second conductive contacts 300 and 200 connected to the gate electrodes GE may be efficiently disposed within a limited area of the second extension region EXR2 of the stacked structure ST. In addition, even when the number of the gate electrodes GE of the stacked structure ST and the number of conductive contacts respectively connected to the gate electrodes GE increase, an increase in an area of the second extension region EXR2 of the stacked structure ST for placement of the conductive contacts may be minimized. Therefore, high integration of the three-dimensional semiconductor device may be facilitated.

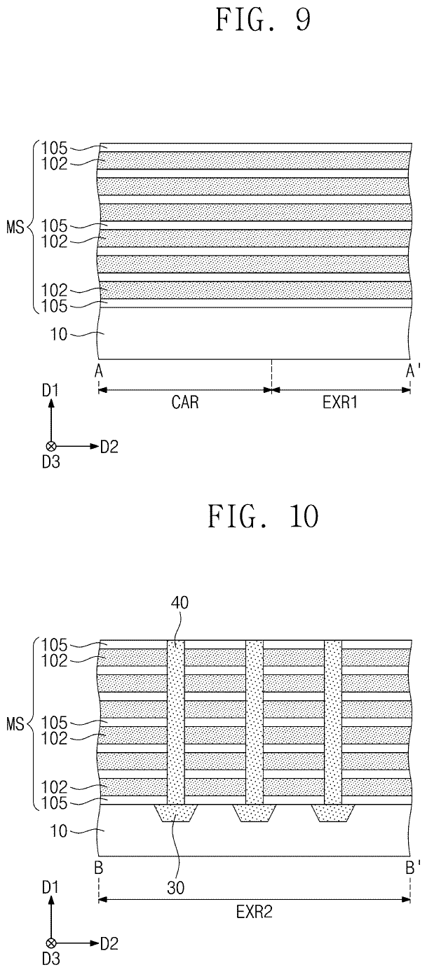

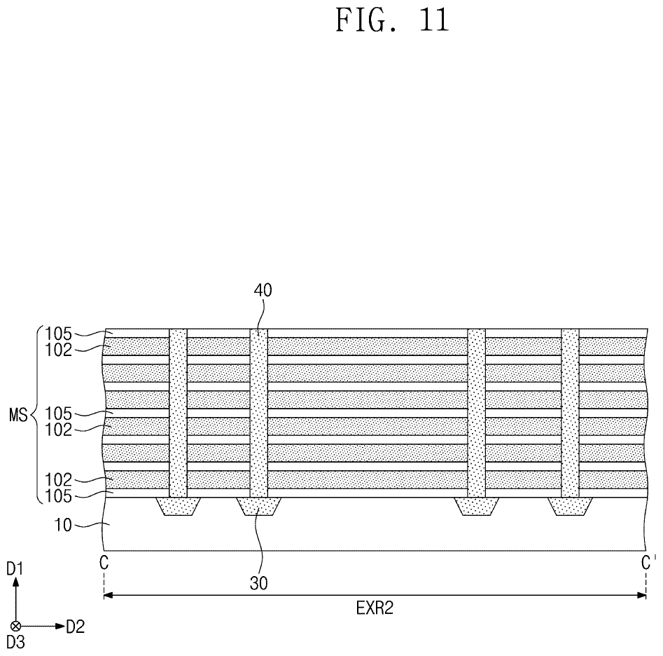

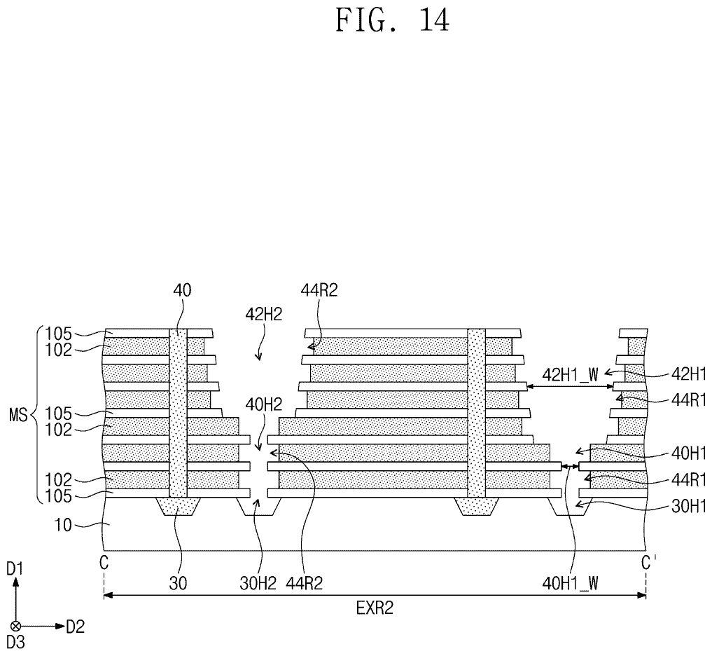

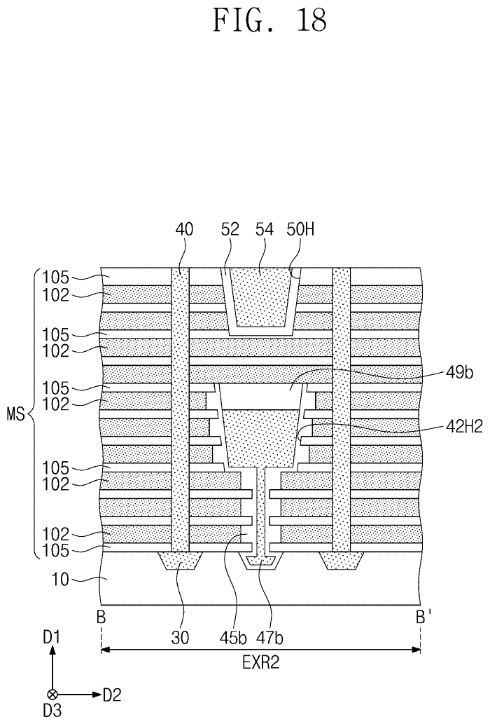

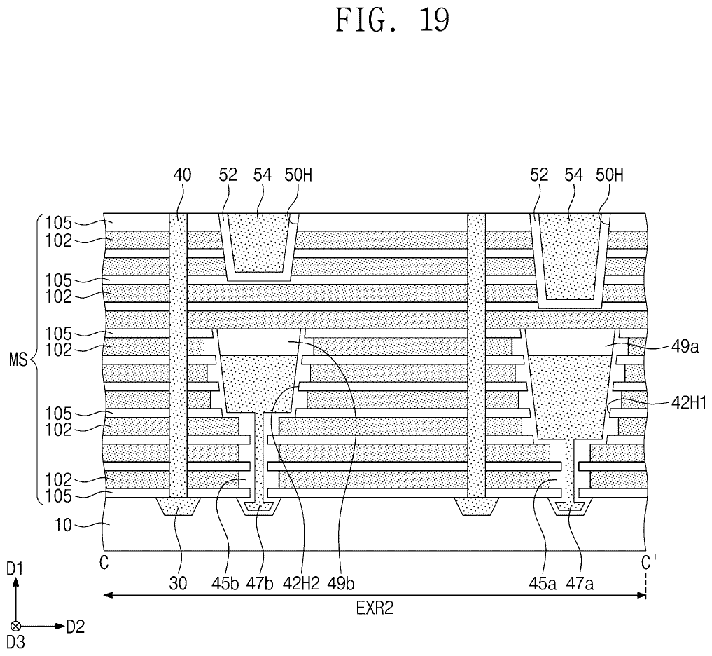

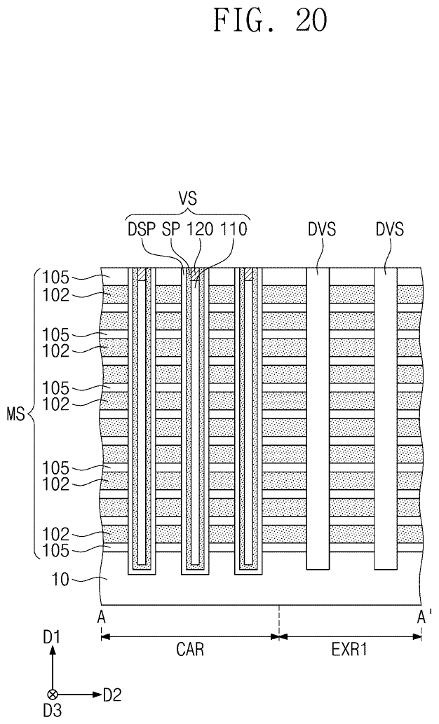

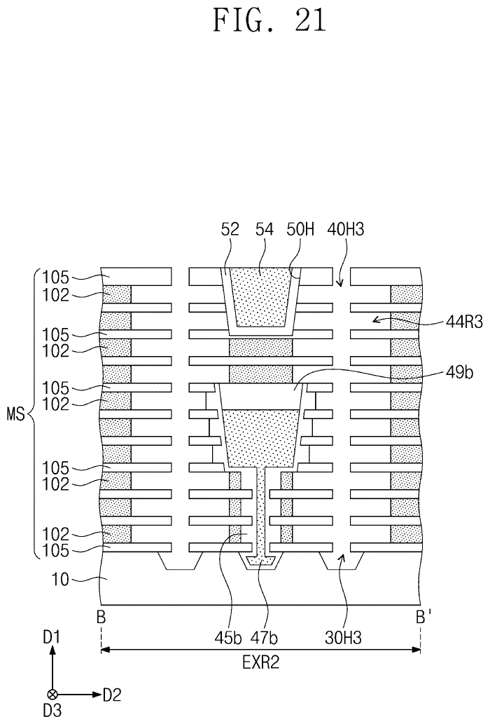

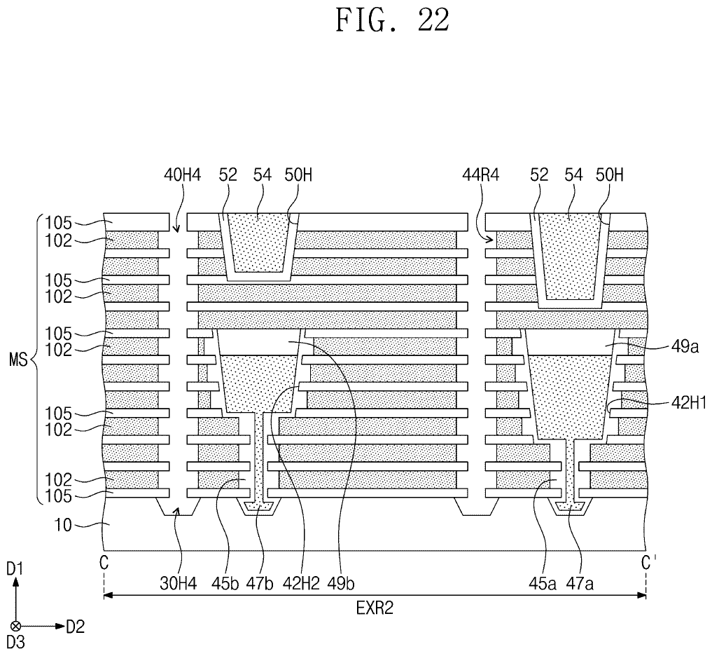

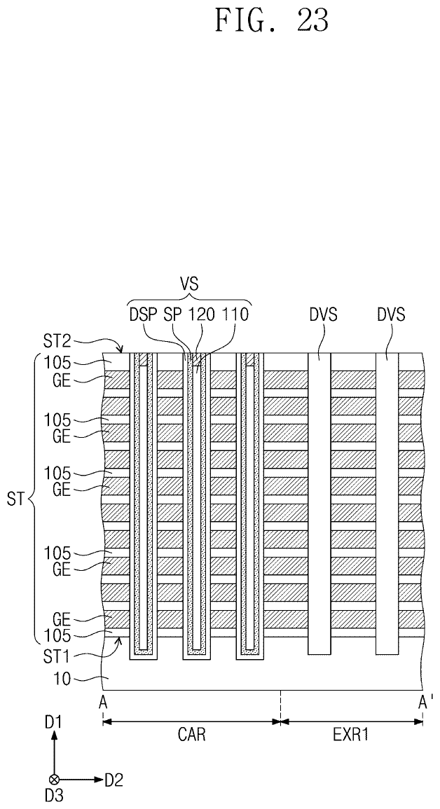

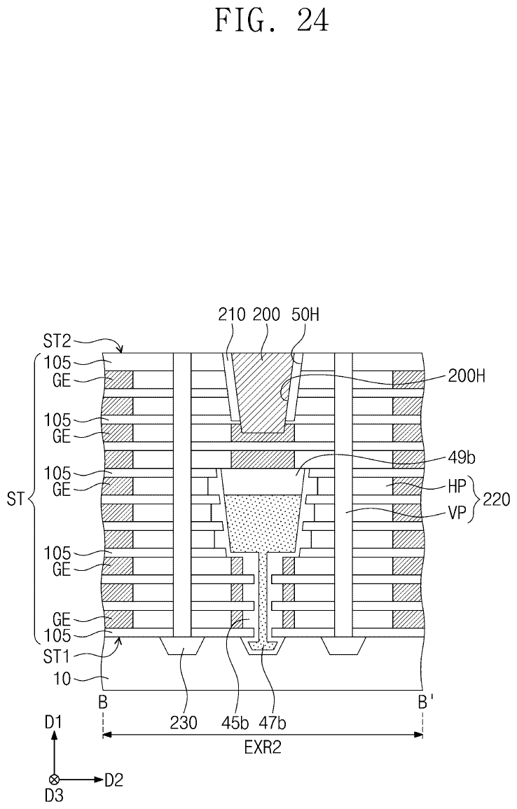

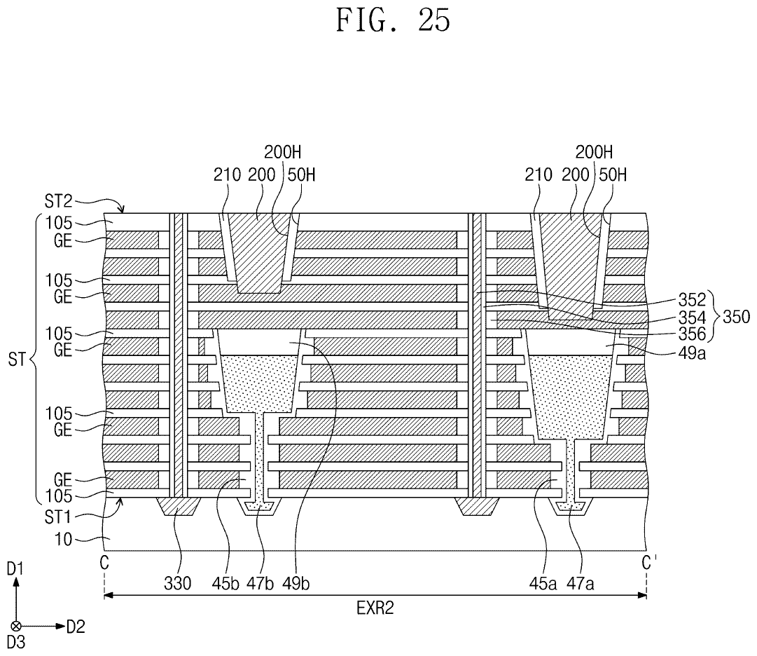

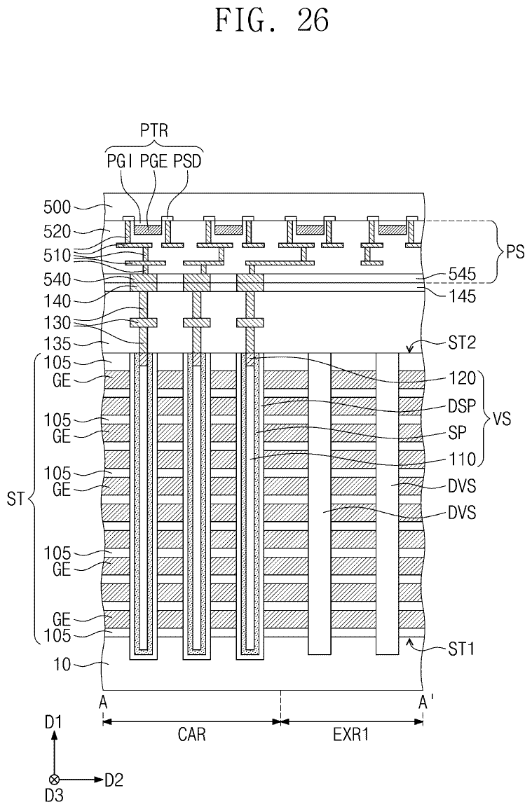

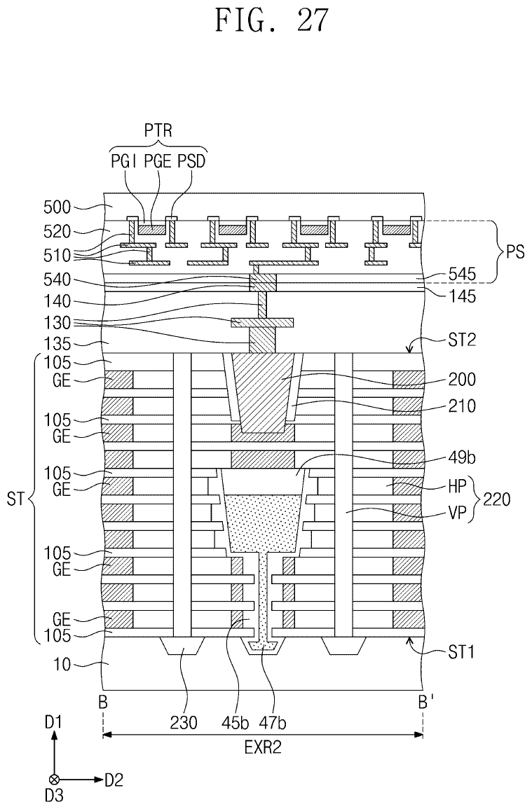

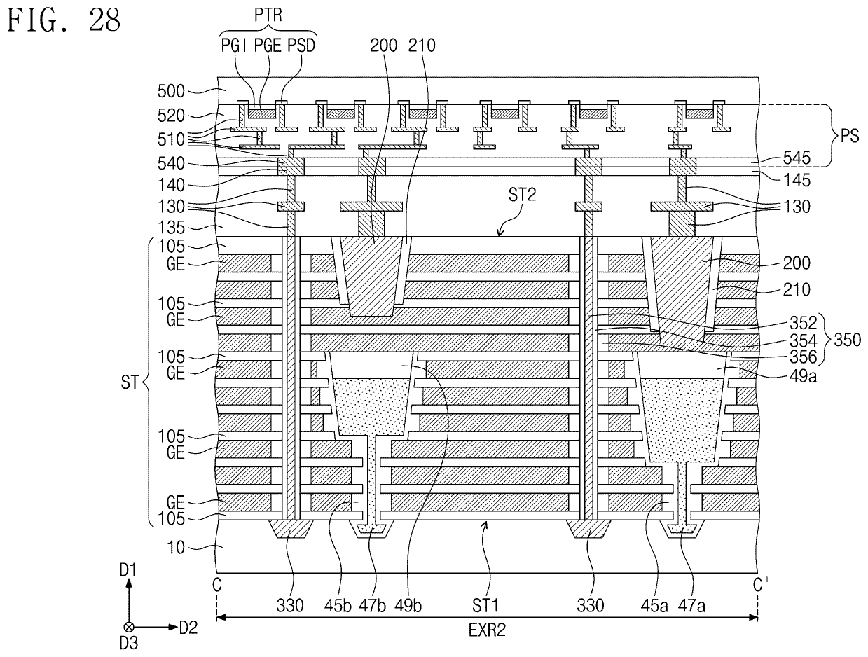

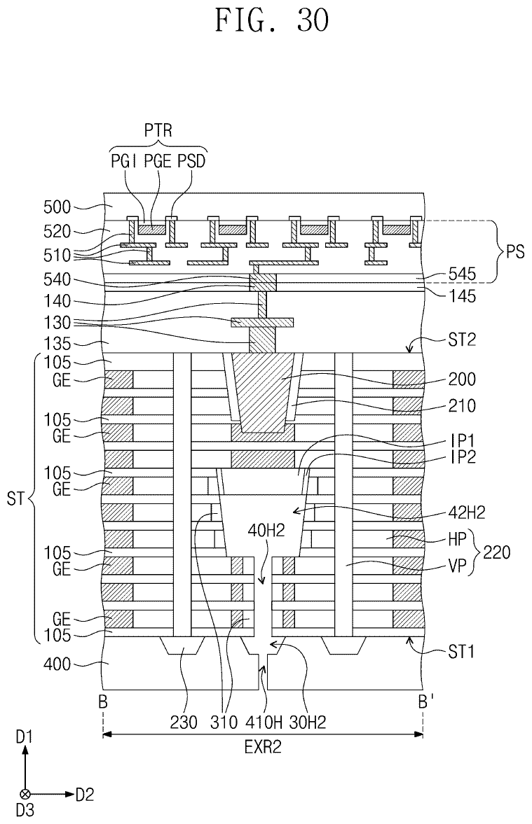

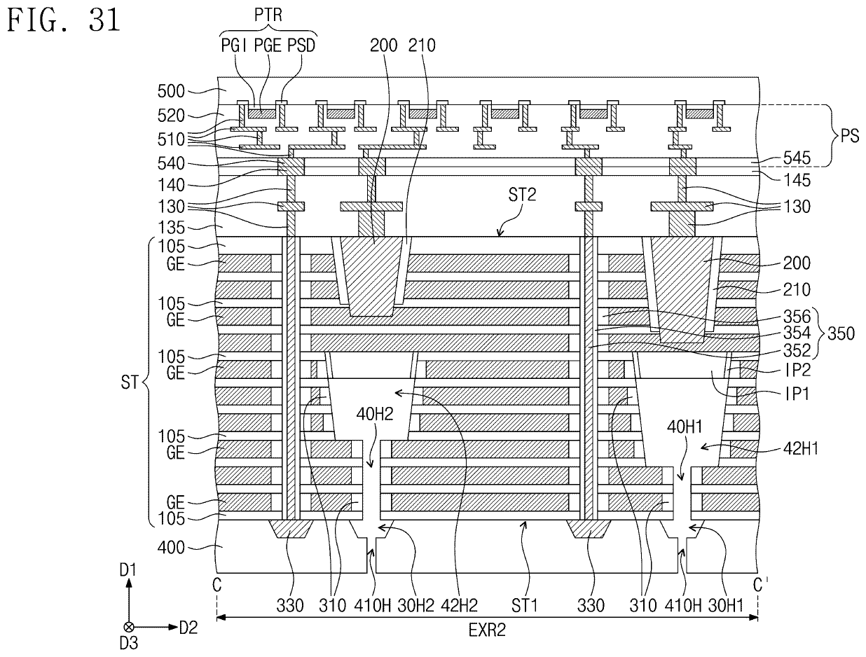

FIGS. 9 to 33 are cross-sectional views for illustrating a method of manufacturing a three-dimensional semiconductor memory device according to some embodiments of the disclosed concepts. FIGS. 9, 12, 17, 20, 23, 26, and 29 are cross-sectional views corresponding to the line A-A′ of FIG. 5, FIGS. 10, 13, 15, 18, 21, 24, 27, 30, and 32 are cross-sectional views corresponding to the line B-B′ of FIG. 5, and FIGS. 11, 14, 16, 19, 22, 25, 28, 31, and 33 are cross-sectional views corresponding to the line C-C′ of FIG. 5. For the sake of brevity, the same element as the three-dimensional semiconductor memory device described with reference to FIGS. 5 to 8 may be identified by the same reference number without repeating an overlapping description.

Referring to FIGS. 5 and 9 to11, a mold structure MS may be formed on a preliminary substrate 10. The preliminary substrate 10 may be, for example, a semiconductor substrate. The mold structure MS may include insulating layers 105 and sacrificial layers 102 alternately stacked on the preliminary substrate 10 along the first direction D1. The sacrificial layers 102 may include a material having an etch selectivity with respect to the insulating layers 105. In an example, the sacrificial layers 102 may include silicon nitride, and the insulating layers 105 may include silicon oxide. The mold structure MS may extend in the second direction D2 and the third direction D3. The mold structure MS may include a cell region CAR, a first extension region EXR1 extending from the cell region CAR in the second direction D2, and a second extension region EXR2 extending from the first extension region EX R1 in the second direction D2.

Buried sacrificial patterns 30 may be formed in the preliminary substrate 10 below the second extension region EXR2 of the mold structure MS. In an example, the buried sacrificial patterns 30 may be formed in the preliminary substrate 10 before the mold structure MS is formed. The buried sacrificial patterns 30 may be spaced apart from one another in the second direction D2 and the third direction D3.

Vertical sacrificial patterns 40 may be formed in the second extension region EXR2 of the mold structure MS. The vertical sacrificial patterns 40 may be spaced apart from one another in the second direction D2 and the third direction D3 within the second extension region EXR2 of the mold structure MS, and may be respectively disposed on the buried sacrificial patterns 30. Each of the vertical sacrificial patterns 40 may penetrate the mold structure MS along the first direction D1. The buried sacrificial patterns 30 and the vertical sacrificial patterns 40 may include, for example, a carbon-containing material, polycrystalline silicon, and/or silicon nitride, or the like.

Referring to FIGS. 5 and 12 to 14, a first vertical hole 40H1 may be formed by removing one of the vertical sacrificial patterns 40. The first vertical hole 40H1 may expose one of the buried sacrificial patterns 30. A first buried hole 30H1 may be formed below the first vertical hole 40H1 and within the preliminary substrate 10 by removing the exposed buried sacrificial pattern 30. An upper portion of the mold structure MS, which is exposed by the first vertical hole 40H1, may be etched, and thus a first contact hole 42H1 may be formed. A remainder of the first vertical hole 40H1 may remain between the first buried hole 30H1 and the first contact hole 42H1. A width 42H1_W of the first contact hole 42H1 in the second direction D2 may be greater than a width 40H1_W of the first vertical hole 40H1 in the second directionD2. According to some embodiments, a size of the first buried hole 30H1 may be increased while the first contact hole 42H1 is formed, but the disclosed concepts is not limited thereto.

The sacrificial layers 102 exposed by the first contact hole 42H1 and the first vertical hole 40H1 may be recessed laterally to form first recess regions 44R1. Recessing the sacrificial layers 102 laterally may be performed, for example, using a wet etch process. The first recess regions 44R1 may extend between the insulating layers 105 and may be spaced apart from one another in the first direction D1. The first buried hole 30H1, the first vertical hole 40H1, the first contact hole 42H1, and the first recess regions 44R1 may be connected to one another to form one empty region.

A second vertical hole 40H2 and a second buried hole 30H2 may be formed by removing another of the vertical sacrificial patterns 40 and another of the buried sacrificial patterns 30. An upper portion of the mold structure MS, which is exposed by the second vertical hole 40H2, may be etched to form a second contact hole 42H2. According to some embodiments, a size of the second buried hole 30H2 may be increased while the second contact hole 42H2 is formed, but the disclosed concepts is not limited thereto. The sacrificial layers 102 exposed by the second contact hole 42H2 and the second vertical hole 40H2 may be laterally recessed to form second recess regions 44R2. The second buried hole 30H2, the second vertical hole 40H2, the second contact hole 42H2, and the second recess regions 44R2 may be formed in substantially the same manner as the first buried hole 30H1, the first vertical hole 40H1, the first contact hole 42H1, and the first recess regions 44R1. The second buried hole 30H2, the second vertical hole 40H2, the second contact hole 42H2, and the second recess regions 44R2 may be connected to one another to form one empty region.

Lower surfaces of the first contact hole 42H1 and the second contact hole 42H2 may be positioned at different heights along the first direction D1. Accordingly, the first contact hole 42H1 and the second contact hole 42H2 may respectively expose sacrificial layers 102 located at different heights in the first direction D1, among the sacrificial layer 102.

According to some embodiments, the second buried hole 30H2, the second vertical hole 40H2, the second contact hole 42H2, and the second recess regions 44R2 may be formed simultaneously with the first buried hole 30H1, the first vertical hole 40H1, the first contact hole 42H1, and the first recess regions 44R1. According to embodiments, the second buried hole 30H2, the second vertical hole 40H2, the second contact hole 42H2 and the second recess regions 44R2 may be formed after the first buried hole 30H1, the first vertical hole 40H1, the first contact hole 42H1 and the first recess regions 44R1 are formed.

Referring to FIGS. 5, 12, 15, and 16, a first insulating layer 45a, a first contact sacrificial layer 47a, and a second insulating layer 49a may be formed to fill the first buried hole 30H1, the first vertical hole 40H1, the first contact hole 42H1, and the first recess regions 44R1. The first insulating layer 45a may fill the first recess regions 44R1 and may be formed to conformally cover inner surfaces of the first contact hole 42H1, the first vertical hole 40H1, and the first buried hole 30H1. The first contact sacrificial layer 47a may fill a remainder of the first buried hole 30H1 and a remainder of the first vertical hole 40H1, and may be formed to fill a portion of the first contact hole 42H1. The second insulating layer 49a may be formed to fill a remainder of the first contact hole 42H1. The first contact sacrificial layer 47a may include a material having an etching selectivity with respect to the first insulating layer 45a and the second insulating layer 49a. As an example, the first insulating layer 45a and the second insulating layer 49a may include silicon oxide, and the first contact sacrificial layer 47a may include silicon nitride, polycrystalline silicon, and/or a carbon-containing material.

A third insulating layer 45b, a second contact sacrificial layer 47b, and a fourth insulating layer 49b may be formed to fill the second buried hole 30H2, the second vertical hole 40H2, the second contact hole 42H2, and the second recess regions 44R2. The third insulating layer 45b may fill the second recess regions 44R2 and may be formed to conformally cover inner surfaces of the second contact hole 42H2, the second vertical hole 40H2, and the second buried hole 30H2. The second contact sacrificial layer 47b may fill a remainder of the second buried hole 30H2 and a remainder of the second vertical hole 40H2, and may be formed to fill a portion of the second contact hole 42H2. The fourth insulating layer 49b may be formed to fill a remainder of the second contact hole 42H2. The second contact sacrificial layer 47b may include a material having an etching selectivity with respect to the third insulating layer 45b and the fourth insulating layer 49b. As an example, the third insulating layer 45b and the fourth insulating layer 49b may include silicon oxide, and the second contact sacrificial layer 47b may include silicon nitride, polycrystalline silicon, and/or a carbon-containing material.

According to some embodiments, the first insulating layer 45a, the first contact sacrificial layer 47a, and the second insulating layer 49a may be formed simultaneously with the third insulating layer 45b, the second contact sacrificial layer 47b, and the fourth insulating layer 49b, respectively.

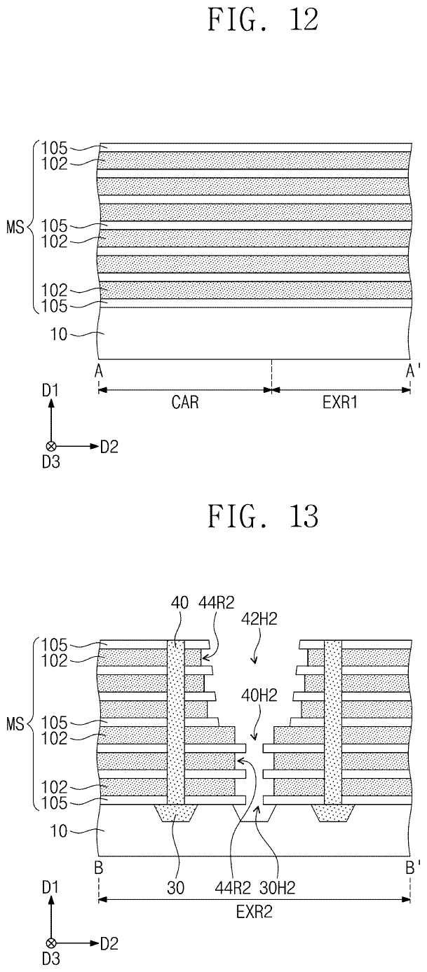

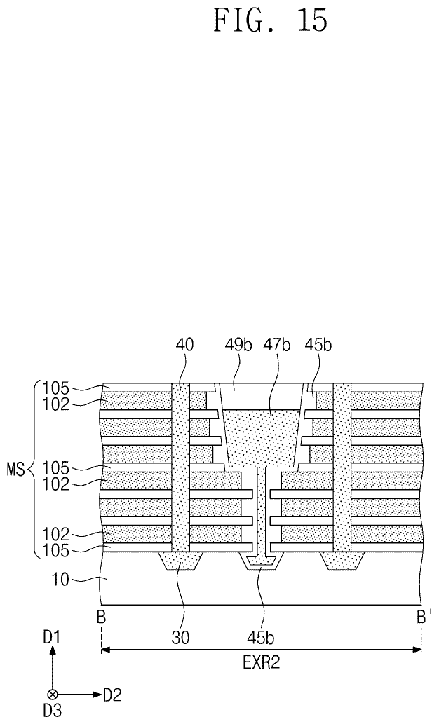

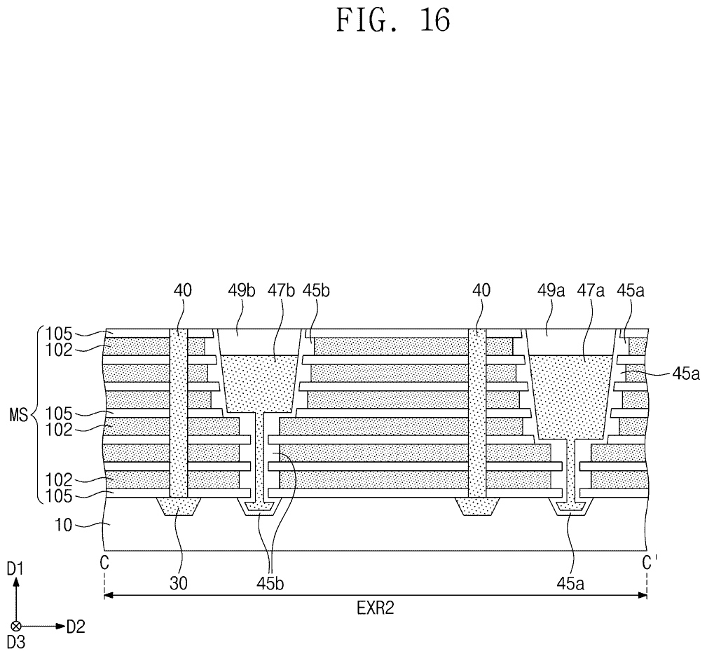

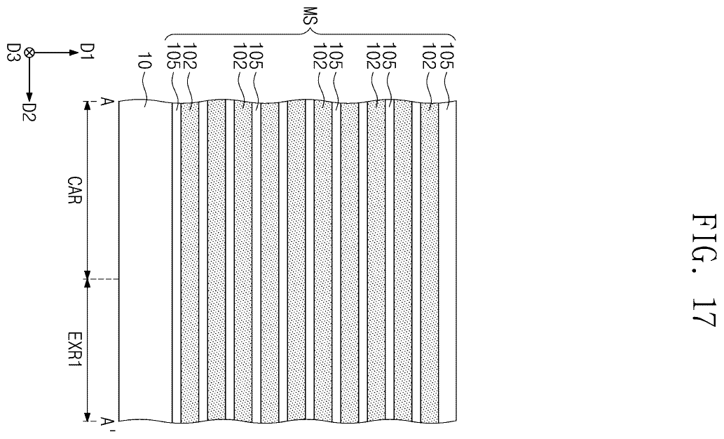

Referring to FIGS. 5 and 17 to 19, additional sacrificial layers 102 and additional insulating layers 105 may be alternately and repeatedly formed on the mold structure MS, the second insulating layer 49a, the fourth insulating layer 49b, and the vertical sacrificial patterns 40, which are shown in FIGS. 12, 15, and 16. Accordingly, the mold structure MS may further include the additional sacrificial layers 102 and the additional insulating layers 105. A lowermost one among the additional sacrificial layers 102 may cover uppermost surfaces of the second insulating layer 49a, the fourth insulating layer 49b, and the vertical sacrificial patterns 40, which are illustrated in FIGS. 15 and 16. The lowermost additional sacrificial layer 102 may be interposed between a lowermost additional insulating layer 105 of the additional insulating layers 105 and the second insulating layer 49a, between the lowermost additional insulating layer 105 and the fourth insulating layer 49b, and between the lowermost additional insulating layer 105 and the vertical sacrificial patterns 40. The vertical sacrificial patterns 40 may then extend through the additional sacrificial layers 102 and the additional insulating layers 105 along the first direction D1. Extending the vertical sacrificial patterns 40 may include, for example, forming extensions penetrating the additional sacrificial layers 102 and the additional insulating layers 105, on the vertical sacrificial patterns 40, respectively.

Third contact holes 50H may be formed in the second extension region EXR2 of the mold structure MS. The third contact holes 50H may be formed between the vertical sacrificial patterns 40 and on the first and second contact holes 42H1 and 42H2. The third contact holes 50H may be spaced apart from the first and second contact holes 42H1 and 42H2 along the first direction D1. According to some embodiments, the third contact holes 50H may be aligned with the first and second contact holes 42H1 and 42H2, respectively, along the first direction D1, and may vertically overlap the first and second contact holes 42H1 and 42H2, respectively, according to the first direction D1.

Each of the third contact holes 50H may penetrate an upper portion of the mold structure MS, and a lower surface of each of the third contact holes 50H may expose a corresponding one of the insulating layers 105. The lower surfaces of the third contact holes 50H may be positioned at different heights along the first direction D1.

A spacer insulating layer 52 may be formed to fill a portion of each of the third contact holes 50H. The spacer insulating layer 52 may conformally cover the inner surface of each of the third contact holes 50H. A third contact sacrificial layer 54 may be formed on the spacer insulating layer 52 to fill a remainder of each of the third contact holes 50H. The third contact sacrificial layer 54 may include a material having an etching selectivity with respect to the spacer insulating layer 52. As an example, the spacer insulating layer 52 may include silicon oxide, and the third contact sacrificial layer 54 may include a carbon-containing material, silicon nitride, polycrystalline silicon, or the like.

Referring to FIGS. 5 and 20 to 22, a vertical structure VS may be formed in the cell region CAR of the mold structure MS. The vertical structure VS may penetrate the mold structure MS along the first direction D1 and may extend into the preliminary substrate 10. The vertical structure VS may include a vertical semiconductor pattern SP penetrating the mold structure MS along the first direction D1, a data storage pattern DSP between the vertical semiconductor pattern SP and the mold structure MS, an internal insulating pattern 110 disposed inside the vertical semiconductor pattern SP, and a conductive pad 120 on the internal insulating pattern 110. Forming the vertical structure VS may include, for example, forming a cell vertical hole that penetrates the mold structure MS along the first direction D1 and extends inside the preliminary substrate 10, forming a data storage layer that fills a portion of the cell vertical hole, forming a vertical semiconductor layer that fills a portion of the cell vertical hole on the data storage layer, forming an internal insulating layer that fills a remainder of the cell vertical hole on the vertical semiconductor layer, forming the data storage pattern DSP, the vertical semiconductor pattern SP, and the internal insulating pattern 110 by planarizing the internal insulating layer, the vertical semiconductor layer and the data storage layer until an upper surface of the mold structure MS is exposed, recessing an upper portion of the internal insulating pattern 110 to form an empty region, and forming the conductive pad 120 that fills the empty region on the internal insulating pattern 110.

A dummy vertical structure DVS may be formed in the first extension region EXR1 of the mold structure MS. The dummy vertical structure DVS may penetrate the mold structure MS along the first direction D1 and may extend into the preliminary substrate 10. As an example, forming the dummy vertical structure DVS may include forming a dummy vertical hole penetrating the mold structure MS along the first direction D1 and extending inside the preliminary substrate 10, forming an insulating layer filling the dummy vertical hole, and planarizing the insulating layer until an upper surface of the mold structure MS is exposed. As another example, the dummy vertical structure DVS may have the same thin film structure as the vertical structure VS, and may be formed in substantially the same manner as the vertical structure VS.

The vertical sacrificial patterns 40 may be removed, and accordingly, a third vertical hole 40H3 and a fourth vertical hole 40H4 may be formed in the second extension region EXR2 of the mold structure MS. The third vertical hole 40H3 and the fourth vertical hole 40H4 may be horizontally (for example, in the second direction D2 or the third direction D3) spaced apart from one another in the second extension region EXR2 of the mold structure MS. Each of the third vertical hole 40H3 and the fourth vertical hole 40H4 may penetrate the mold structure MS along the first direction D1. The third vertical hole 40H3 and the fourth vertical hole 40H4 may expose the buried sacrificial patterns 30, respectively.

A third buried hole 30H3 may be formed as the buried sacrificial pattern 30 exposed by the third vertical hole 40H3 is removed, and a fourth buried hole 30H4 may be formed as the buried sacrificial pattern 30 exposed by the fourth vertical hole 40H4 is removed. The third buried hole 30H3 and the fourth buried hole 30H4 may be formed under the second extension region EXR2 of the mold structure MS and in the preliminary substrate 10.

The sacrificial layers 102 exposed by the third vertical hole 40H3 may be laterally recessed to form third recess regions 44R3. The sacrificial layers 102 exposed by the fourth vertical hole 40H4 may be laterally recessed to form fourth recess regions 44R4. Recessing the sacrificial layers 102 laterally may be performed, for example, using a wet etch process. The third recess regions 44R3 may extend between the insulating layers 105 and may be spaced apart from one another in the first direction D1. The fourth recess regions 44R4 may extend between the insulating layers 105 and may be spaced apart from one another in the first direction D1. The third vertical hole 40H3, the third buried hole 30H3, and the third recess regions 44R3 may be connected to one another to form one empty region. The fourth vertical hole 40H4, the fourth buried hole 30H4, and the fourth recess regions 44R4 may be connected to one another to form one empty region.

Referring to FIGS. 5 and 23 to 25, a buried insulation pattern 230 may be formed to fill the third buried hole 30H3, and a support structure 220 may be formed to filled the third vertical hole 40H3 and the third recess regions 44R3. The support structure 220 may include a vertical portion VP filling the third vertical hole 40H3 and horizontal portions HP filling the third recess regions 44R3. Forming the buried insulating pattern 230 and the support structure 220 may include, for example, forming an insulating layer filling the third buried hole 30H3, the third vertical hole 40H3, and the third recess regions 44R3, and planarizing the insulating layer until an upper surface of the mold structure MS is exposed.

A buried conductive pattern 330 may be formed to fill the fourth buried hole 30H4, and a through electrode structure 350 may be formed to filled the fourth vertical hole 40H4 and the fourth recess regions 44R4. The through electrode structure 350 may include horizontal insulating patterns 356 that fill the fourth recess regions 44R4, a vertical insulating pattern 354 that fills a portion of the fourth vertical hole 40H4, and a vertical electrode pattern 352 that fills a remainder of the fourth vertical holes 40H4. Forming the buried conductive pattern 330 and the through electrode structure 350 may include, for example, forming an insulating layer filling the fourth recess regions 44R4 and conformally covering an inner surface of the fourth vertical hole 40H4, and forming a conductive layer filling the fourth buried hole 30H4 and filling a remainder of the fourth vertical hole 40H4.

The sacrificial layers 102 of the mold structure MS may be replaced with gate electrodes GE. Replacing the sacrificial layers 102 with the gate electrodes GE may include, for example, forming isolation trenches that penetrate the mold structure MS along the first direction D1 and expose side surfaces of the sacrificial layers 102, forming gate regions between the insulating layers 105 by removing the sacrificial layers 102 exposed by the isolation trenches, and forming a gate electrode layer that fills the gate regions. The gate electrodes GE and the insulating layers 105 may be alternately and repeatedly stacked along the first direction D1, and may be referred to as a stacked structure ST. The stacked structure ST may include the cell region CAR, the first extension region EXR1 extending from the cell region CAR in the second direction D2, and the second extension region EXR2 extending from the first extension regionEXR 1 in the second directionD2. The stacked structure ST may have a front surface ST1 and a rear surface ST2 opposite to one another in the first direction D1. The front surface ST1 of the stacked structure ST may be adjacent to the preliminary substrate 10.

Separation structures WLC may be formed to fill the separation trenches, respectively. The separation structures WLC may be spaced apart from one another in the third direction D3 with the stacked structure ST interposed therebetween, and may extend in the second direction D2 along the cell region CAR and the first and second extension regions EXR1 and EXR2 of the stacked structure ST. The separation structures WLC may cover side surfaces of the stacked structure ST, which are opposite to one another in the third direction D3, respectively.

First cutting patterns CTP1 may be formed in the cell region CAR and the first extension region EXR1 of the stacked structure ST, and may be formed adjacent to the rear surface ST2 of the stacked structure ST. The first cutting patterns CTP1 may be spaced apart from one another in the third direction D3 in the cell region CAR and the first extension region EXR1 of the stacked structure ST, and may extend in the second direction D2. Each of the first cutting patterns CTP1 may extend from the rear surface ST2 of the stacked structure ST into the stacked structure ST, and may be formed to penetrate an upper portion (for example, at least one insulating layer 105 and at least one gate electrode GE) of the stacked structure ST along the first direction D1. Forming the first cutting patterns CTP1 may include, for example, forming first cutting trenches penetrating an upper portion (for example, at least one insulating layer 105 and at least one gate electrode GE) of the stacked structure ST along the first direction D1, and forming an insulating layer filling the first cutting trenches. The first cutting trenches may be spaced apart from one another in the third direction D3 in the cell region CAR and the first extension region EXR1 of the stacked structure ST, and may extend in the second direction D2.

A second cutting pattern CTP2 may be formed in the first extension region EXR1 of the stacked structure ST, and may be formed adjacent to the rear surface ST2 of the stacked structure ST. The second cutting pattern CTP2 may extend in the third direction D3 in the first extension region EXR1 of the stacked structure ST, and may be connected to ends of the first cutting patterns CTP1. The second cutting pattern CTP2 may extend from the rear surface ST2 of the stacked structure ST into the stacked structure ST, and may be formed to penetrate an upper portion (for example, at least one insulating layer 105 and at least one gate electrode GE) of the stacked structure ST along the first direction D1. Forming the second cutting pattern CTP2 may include, for example, forming a second cutting trench penetrating an upper portion (for example, at least one insulating layer 105 and at least one gate electrode GE) of the stacked structure ST along the first direction D1, and forming an insulating layer filling the second cutting trench.

The third contact sacrificial layer 54 may be removed from each of the third contact holes 50H, and thus a first inner hole 200H may be formed in each of the third contact holes 50H. The first inner hole 200H may extend to penetrate the spacer insulating layer 52 along the first direction D1, so that the first inner hole 200H may expose a corresponding gate electrode GE among the gate electrodes GE.

A second conductive contact 200 may be formed to fill the first inner hole 200H, and may be connected (e.g., electrically connected) to the corresponding gate electrode GE. Forming the second conductive contact 200 may include, for example, forming a conductive layer filling the first inner hole 200H. As the first inner hole 200H extends through the spacer insulating layer 52, a remainder of the spacer insulating layer 52 may remain on a side surface of the second conductive contact 200, and may be referred to as a side insulating spacer 210.

Referring to FIGS. 5 and 26 to 28, second wiring patterns 130 may be formed on the rear surface ST2 of the stacked structure ST, and may be formed on the cell region CAR, the first extension region EXR1, and the second extension region EXR2 of the stacked structures ST. The conductive pad 120 of the vertical structure VS, the second conductive contact 200, and the vertical electrode pattern 352 of the through electrode structure 350 may be respectively connected (for example, electrically connected) to corresponding second wiring patterns 130 among the second wiring patterns 130. A second interlayer insulating layer 135 may be formed on the rear surface ST2 of the stacked structure ST, and may be formed on the cell region CAR, the first extension region EXR1, and the second extension region EXR2 of the stacked structures ST. The second interlayer insulating layer 135 may be formed to cover the second wiring patterns 130.

Cell bonding pads 140 may be formed on the second interlayer insulating layer 135, and may be formed on the cell region CAR, the first extension region EXR1, and the second extension region EXR2 of the stacked structure ST. The cell bonding pads 140 may be spaced apart from one another in the second direction D2. Each of the cell bonding pads 140 may be connected (e.g., electrically connected) to a corresponding one of the second wiring patterns 130. A cell bonding insulating layer 145 may be formed on the second interlayer insulating layer 135, and may be formed on the cell region CAR, the first extension region EXR1, and the second extension region EXR2 of the stacked structure ST. The cell bonding insulating layer 145 may extend between the cell bonding pads 140 and may cover side surfaces of the cell bonding pad 140. The cell bonding insulating layer 145 may expose top surfaces of the cell bonding pads 140.

A semiconductor substrate 500 and a peripheral circuit structure PS on the semiconductor substrate 500 may be provided on the rear surface ST2 of the stacked structure ST. The peripheral circuit structure PS may be disposed between the rear surface ST2 of the stacked structure ST and the semiconductor substrate 500.

The peripheral circuit structure PS may include peripheral transistors PTR on the semiconductor substrate 500, peripheral wirings 510 electrically connected to the peripheral transistors PTR, a peripheral insulating layer 520 covering the peripheral transistors PTR and the peripheral wirings 510, peripheral bonding pads 540 connected to the peripheral wirings 510, and a peripheral bonding insulating layer 545 covering the peripheral bonding pads540. Each of the peripheral transistors PTR may include a peripheral gate insulating layer PGI, a peripheral gate electrode PGE, and peripheral source/drain regions PSD. The peripheral bonding pads 540 may contact the cell bonding pads 140, respectively, and the peripheral bonding insulating layer 545 may contact the cell bond insulating layer 145.

Referring to FIGS. 5 and 29 to 31, the preliminary substrate 10 may be removed from the front surface ST1 of the stacked structure ST. Accordingly, on the cell region CAR and the first extension region EXR1 of the stacked structure ST, an end of the vertical structure VS and an end of the dummy vertical structure DVS may protrude from the front surface ST1 of the stacked structures ST. In addition, the buried conductive pattern 330, the buried insulating pattern 230, and the first insulating layer 45a and the third insulating layer 45b filling the first and second buried holes 30H1 and 30H2 may be exposed on the second extension region EXR2 of the stacked structure ST.

A portion of the data storage pattern DSP may be removed from the end of the vertical structure VS. Accordingly, an end portion of the vertical semiconductor pattern SP of the vertical structure VS may be exposed.

A source pattern CSL may be formed on the front surface ST1 of the stacked structure ST, and may be formed on the cell region CAR and the first extension region EXR1 of the stacked structures ST. The source pattern CSL may cover the exposed end of the vertical semiconductor pattern SP, and may cover the end of the dummy vertical structure DVS.

A first interlayer insulating layer 400 may be formed on the front surface ST1 of the stacked structure ST, and may be formed on the second extension region EXR2 of the stacked structure ST. The first interlayer insulating layer 400 may cover the buried conductive pattern 330 and the buried insulating pattern 230, and may cover the first insulating layer 45a and the third insulating layer 45b filling the first and second buried holes 30H1 and 30H2.

Via holes 410H may be formed in the first interlayer insulating layer 400, and the first insulating layer 45a and the third insulating layer 45b filling the first and second buried holes 30H1 and 30H2 may be exposed, respectively. A portion of the first insulating layer 45a and the first contact sacrificial layer 47a may be removed from the first buried hole 30H1, the first vertical hole 40H1, and the first contact hole 42H1 through the via holes 410H, and a portion of the third insulating layer 45b and the second contact sacrificial layer 47b may be removed from the second buried hole 30H2, the second vertical hole 40H2, and the second contact hole 42H2. Remaining portions of the first insulating layer 45a filling the first recess regions 44R1 and remaining portions of the third insulating layer 45b filling the second recess regions 44R2 may be referred to as side insulating patterns 310. The second insulating layer 49a remaining in the first contact hole 42H1 and the fourth insulating layer 49b remaining in the second contact hole 42H2 may be referred to as a first insulating pattern IP1. A remainder of the first insulating layer 45a remaining in the first contact hole 42H1 and a remainder of the third insulating layer 45b remaining in the second contact hole 42H2 may be referred to as a second insulating pattern IP2.

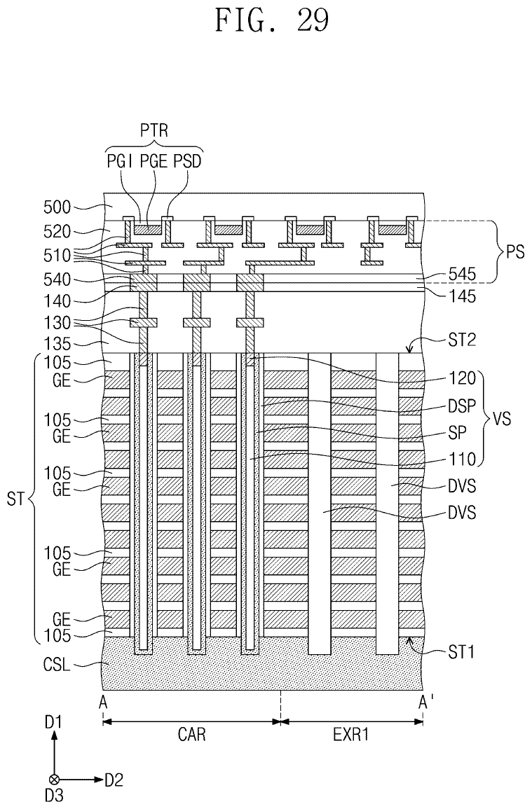

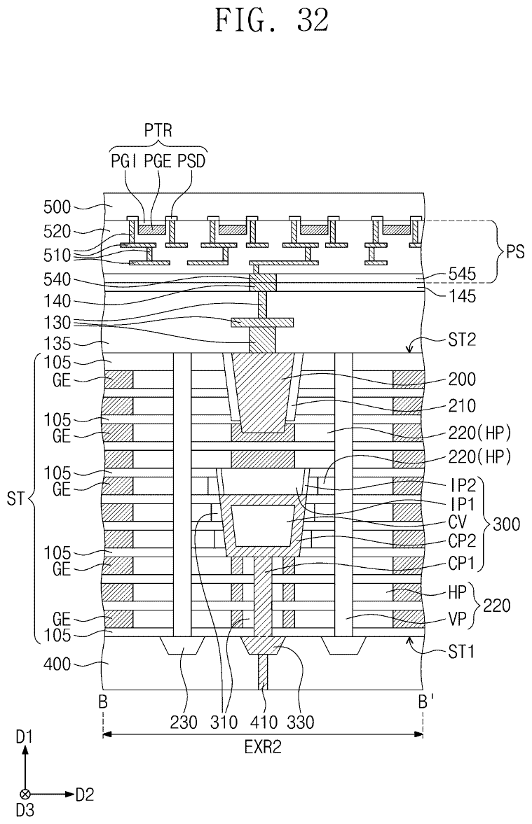

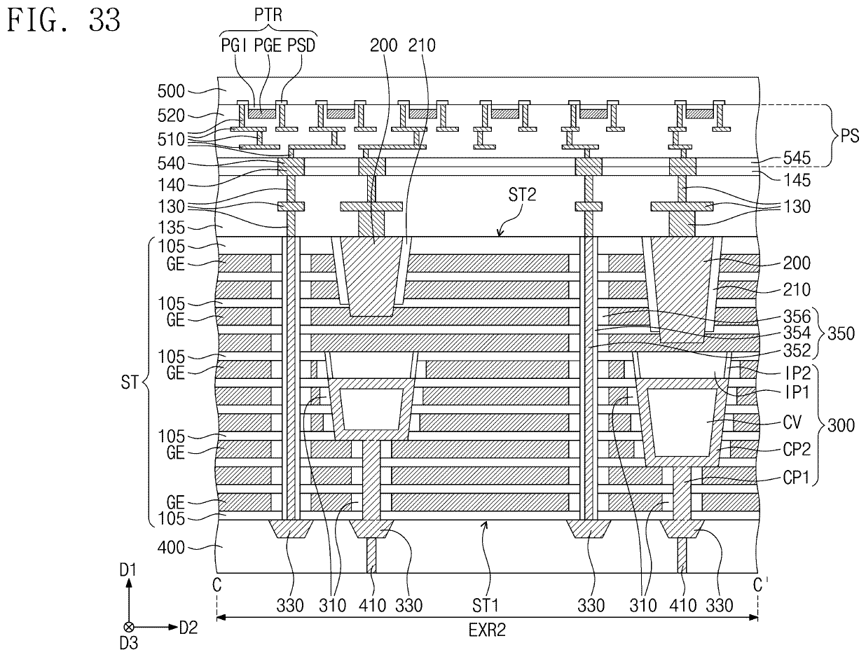

Referring to FIG. 5, FIG. 29, FIG. 32, and FIG. 33, a first contact portion CP1 may be formed to fill each of the first vertical hole 40H1 and the second vertical hole 40H2, and a second contact portion CP2 may be formed to fill each of the first contact hole 42H1 and the second contact hole 42H2. According to some embodiments, the second contact portion CP2 may fill a portion of each of the first contact hole 42H1 and the second contact hole 42H2, and accordingly, a void CV may be formed inside the second contact portion CP2. The first contact portion CP1, the second contact portion CP2, the first insulating pattern IP1, and the second insulating pattern IP2 may be referred to as a first conductive contact 300. According to some embodiments, the first conductive contact 300 may further include the void CV in the second contact portion CP2.

An additional buried conductive pattern 330 may be formed to fill each of the first and second buried holes 30H1 and 30H2. First wiring contacts 410 may be formed to fill the via holes 410H. Forming the first contact portion CP1, the second contact portion CP2, the additional buried conductive pattern 330, and the first wiring contacts 410 may include, for example, forming a conductive layer filling the first contact hole 42H1, the second contact hole 42H2, the first vertical hole 40H1, the second vertical hole 40H2, the first and second buried holes 30H1 and 30H2, and the via holes 410H.

Referring again to FIGS. 5 to 8, additional first wiring contacts 410 may be formed on the buried conductive patterns 330. First wiring lines 420 may be formed in the first interlayer insulating layer 400, and may be connected (e.g., electrically connected) to the first wiring contacts 410. FIGS. 6 to 8 show a state in which the stacked structure ST of FIGS. 29, 32, and 33 is upside down.

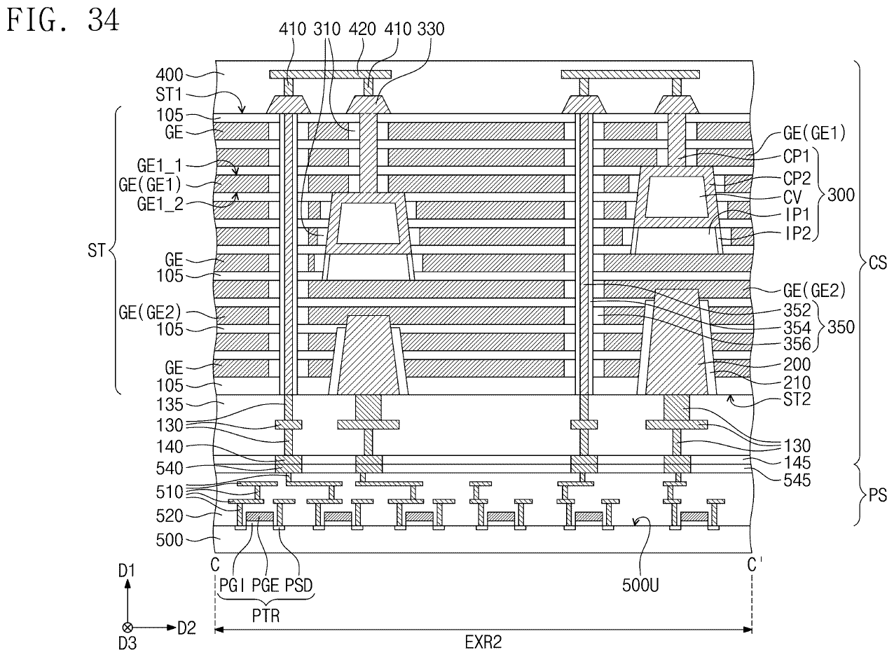

FIG. 34 is a cross-sectional view corresponding to the line C-C′ of FIG. 5 for illustrating a three-dimensional semiconductor memory device according to some embodiments of the disclosed concepts. For simplicity of description, differences from the three-dimensional semiconductor memory device described with reference to FIGS. 5 to 8 will be mainly described.

Referring to FIG. 34, the plurality of first conductive contacts 300 may be respectively connected (e.g., electrically connected) to corresponding first gate electrodes GE1 among the gate electrodes GE, and the corresponding first gate electrode GE1 may be positioned at different heights along the first direction D1. According to some embodiments, the first insulating patterns IP1 of the plurality of first conductive contacts 300 may be positioned at different heights along the first direction D1, and the second insulating patterns IP2 of the plurality of first conductive contacts 300 may be positioned at different heights along the first directions D1.

Except for the differences described above, the three-dimensional semiconductor memory device according to the present embodiments is substantially the same as the three-dimensional semiconductive memory device described with reference to FIGS. 5 to 8.

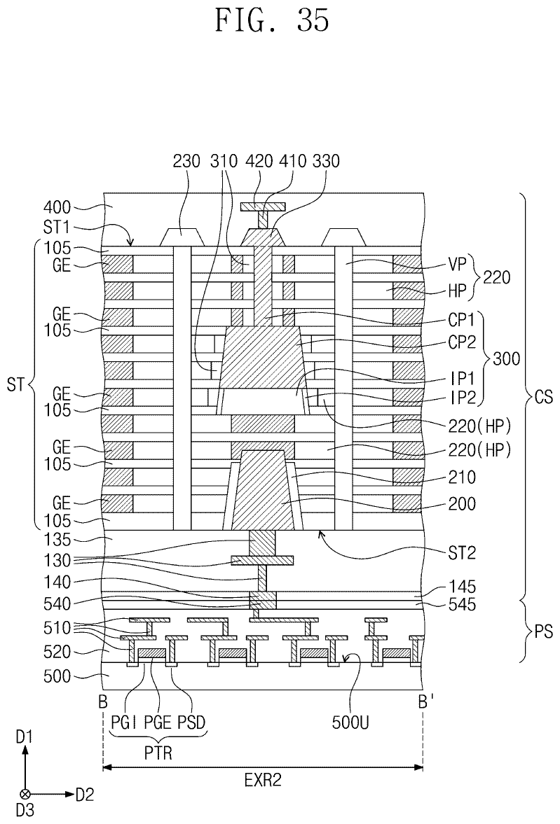

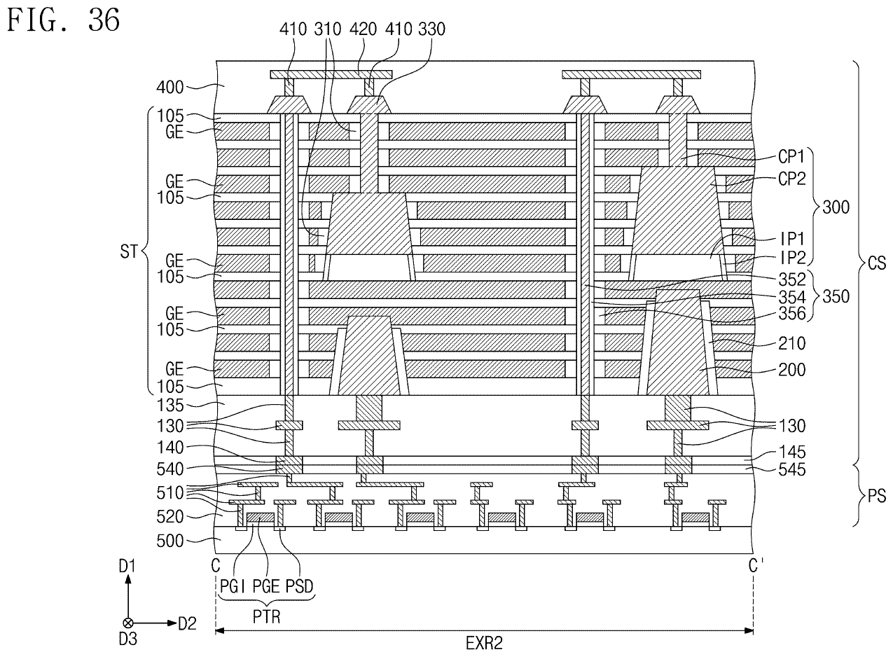

FIGS. 35 and 36 are cross-sectional views corresponding to the line B-B′ and the line C-C′ of FIG. 5, respectively, for illustrating a three-dimensional semiconductor memory device according to some embodiments of the disclosed concepts. For simplicity of description, differences from the three-dimensional semiconductor memory device described with reference to FIGS. 5 to 8 will be mainly described.

Referring to FIGS. 35 and 36, the first conductive contact 300 may include the first contact portion CP1, the second contact portion CP2, and the first and second insulating patterns IP1 and IP2. According to some embodiments, the first conductive contact 300 may not include the void CV in the second contact portion CP2 described with reference to FIGS. 5 to 8. The second contact portion CP2 may have a pillar shape extending in the first direction D1.

Except for the differences described above, the three-dimensional semiconductor memory device according to the present embodiments is substantially the same as the three-dimensional semiconductive memory device described with reference to FIGS. 5 to 8.

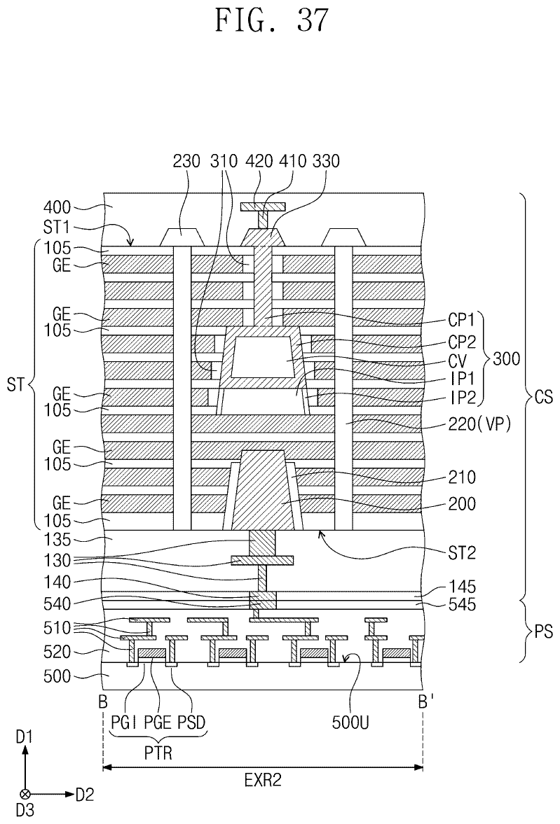

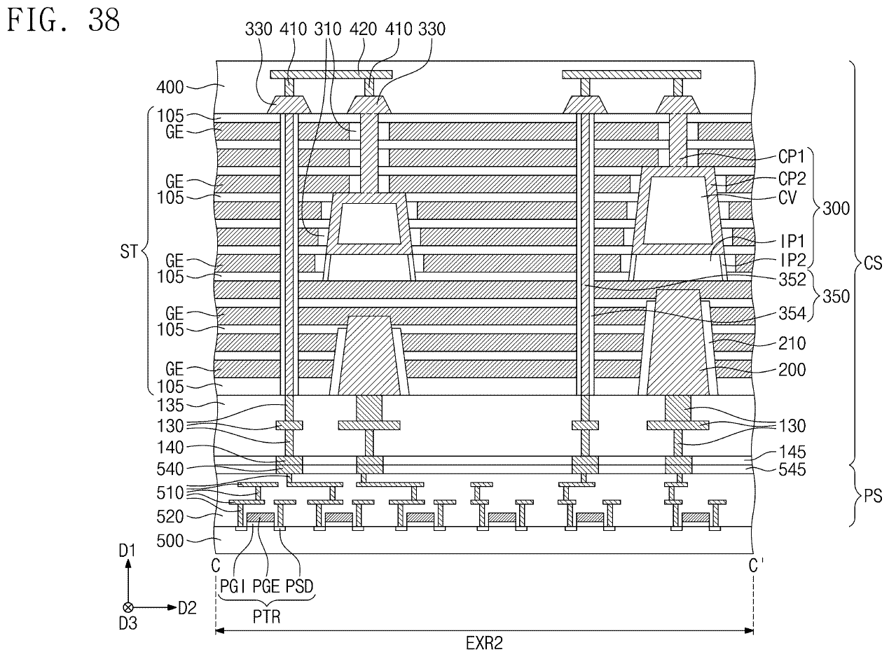

FIGS. 37 and 38 are cross-sectional views corresponding to the line B-B′ and the line C-C′ of FIG. 5, respectively, for illustrating a three-dimensional semiconductor memory device according to some embodiments of the disclosed concepts. For simplicity of description, differences from the three-dimensional semiconductor memory device described with reference to FIGS. 5 to 8 will be mainly described.

Referring to FIGS. 37 and 38, according to some embodiments, each of the support structures 220 may include a vertical portion VP penetrating the stacked structure ST along the first direction D1, and may not include the horizontal portions HP described with reference to FIGS. 5 to 8. Accordingly, each of the support structures 220 may have a pillar shape penetrating the stacked structure ST along the first direction D1, and the gate electrodes GE of the stacked structure ST may be in contact with a side surface of the vertical portion VP of each of the support structures 220.

The through electrode structure 350 may include the vertical electrode pattern 352 penetrating the stacked structure ST along the first direction D1, and the vertical insulating pattern 354 interposed between the vertical electrode pattern352 and the stacked structure ST and penetrating the stacked structure ST along the first direction D1, and may not include the horizontal insulating patterns 356 described with reference to FIGS. 5 to 8. Accordingly, the through-electrode structure 350 may have a pillar shape penetrating the stacked structure ST along the first direction D1, and the gate electrodes GE of the stacked structure ST may be in contact with a side surface of the vertical insulation pattern 354.

Except for the differences described above, the three-dimensional semiconductor memory device according to the present embodiments is substantially the same as the three-dimensional semiconductive memory device described with reference to FIGS. 5 to 8.

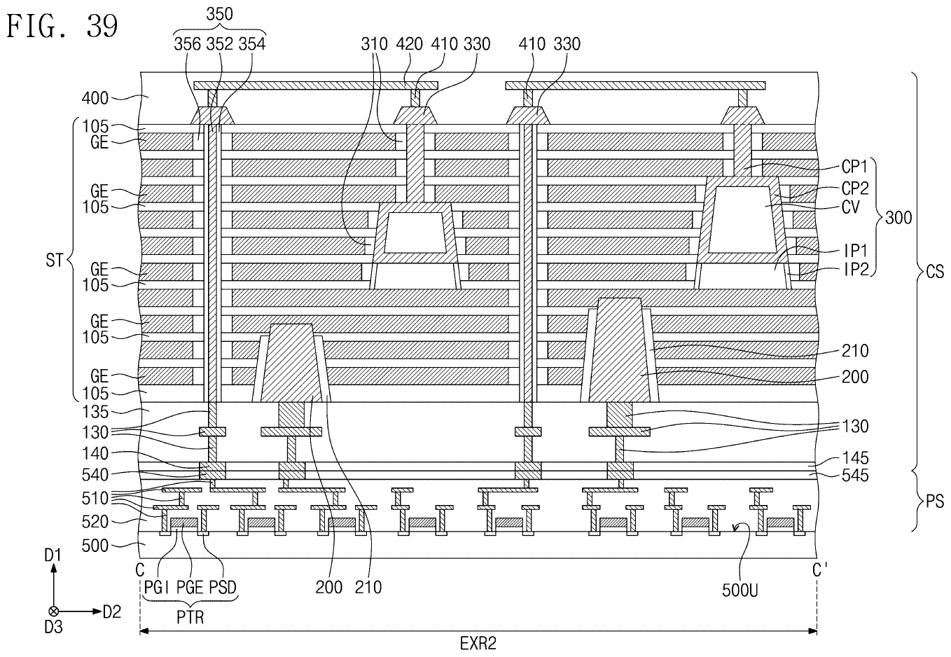

FIG. 39 is a cross-sectional view corresponding to the line C-C′ of FIG. 5 for illustrating a three-dimensional semiconductor memory device according to some embodiments of the disclosed concepts. For simplicity of description, differences from the three-dimensional semiconductor memory device described with reference to FIGS. 5 to 8 will be mainly described.

Referring to FIG. 39, according to some embodiments, the first conductive contact 300 and the second conductive contact 200 may be spaced apart from one another in the first direction D1 in the second extension region EXR2 of the stacked structure ST, and may be offset from one another along a direction parallel to the upper surface 500U of the semiconductor substrate 500 (for example, the second direction D2 or the third direction D3). That is, the first conductive contact 300 and the second conductive contact 200 may not be aligned with one another along the first direction D1, and may not vertically overlap one another along the first direction D1.

Except for the differences described above, the three-dimensional semiconductor memory device according to the present embodiments is substantially the same as the three-dimensional semiconductive memory device described with reference to FIGS. 5 to 8.

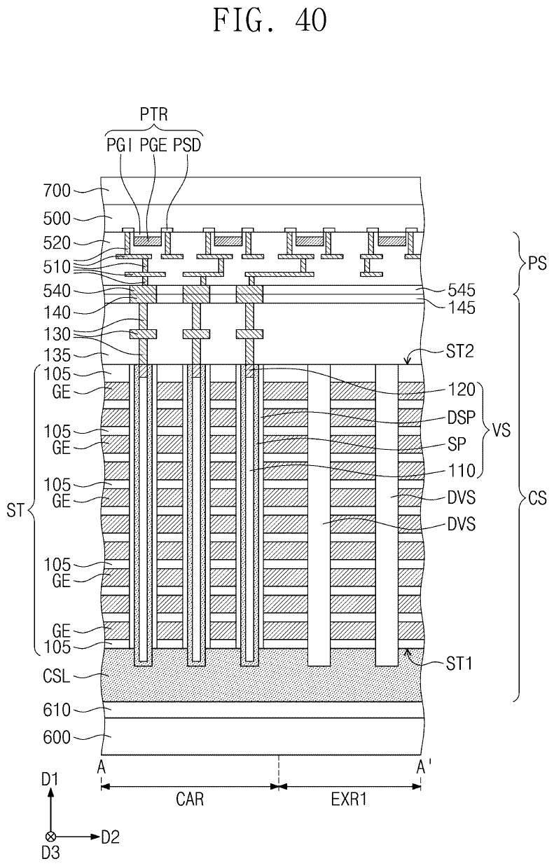

FIG. 40.to 42 are cross-sectional views corresponding to the line A-A′, the line B-B′, and the line C-C′ of FIG. 5, respectively, for illustrating a three-dimensional semiconductor memory device according to some embodiments of the disclosed concepts. For simplicity of description, differences from the three-dimensional semiconductor memory device described with reference to FIGS. 5 to 8 will be mainly described.

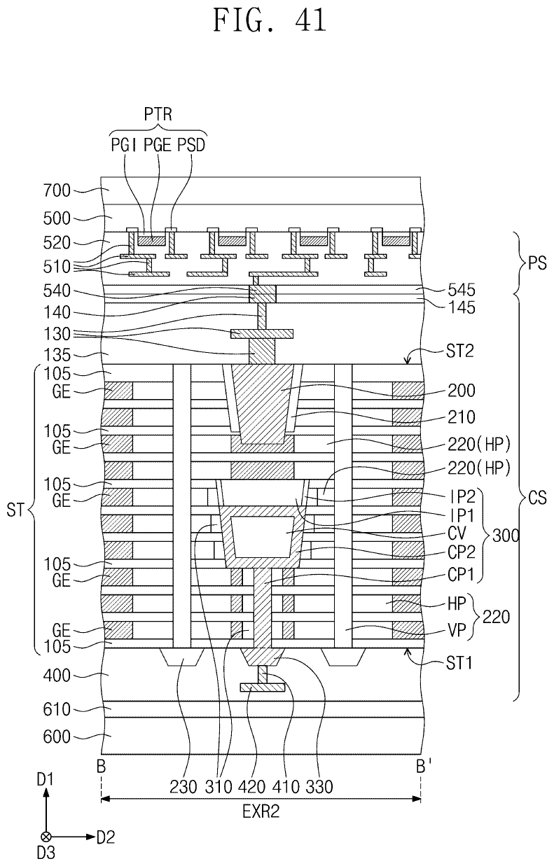

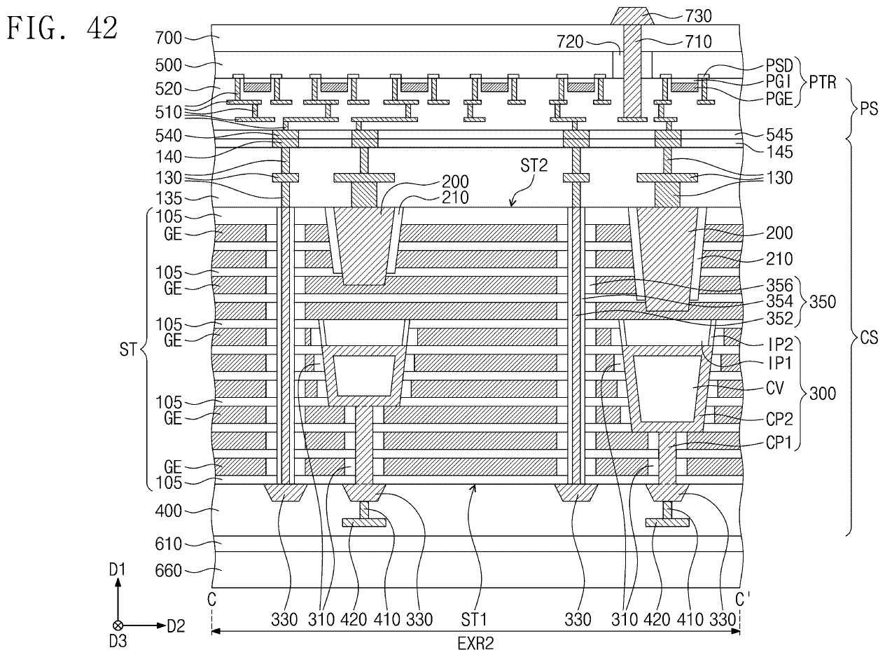

Referring to FIGS. 40 to 42, according to some embodiments, a three-dimensional semiconductor memory device may include the semiconductor substrate 500, the peripheral circuit structure PS, and the cell array structure CS, and may further include a lower substrate 600 and a lower insulating layer 610. The lower insulating layer 610 may be disposed on the lower substrate 600, and the cell array structure CS may be disposed on the lower insulating layer 610. The peripheral circuit structure PS may be disposed on the cell array structure CS, and the semiconductor substrate 500 may be disposed on the peripheral circuit structure PS. The front surface ST1 of the stacked structure ST of the cell array structure CS may face the lower substrate 600, and the rear surface ST2 of the stacked structure ST may face the peripheral circuit structure PS. The lower insulating layer 610 may be interposed between the front surface ST1 of the stacked structure ST and the lower substrate 600. The source pattern CSL, the buried conductive patterns 330, the buried insulating patterns 230, the first wiring patterns 410 and 420, and the first interlayer insulating layer 400 of the cell array structure CS may be interposed between the front surface ST1 of the stacked structure ST and the lower insulating layer 610.

The three-dimensional semiconductor memory device may further include an upper insulating layer 700 on the semiconductor substrate 500, an input/output pad 730 on the upper insulating layer 700, a through-substrate via 710 penetrating through the upper insulating layer 700 and the semiconductor substrate 500 and connected (e.g., electrically connected) to the input/output pads 730, and an insulating spacer 720 interposed between the semiconductor substrate 500 and the through-substrate via 710.

The peripheral circuit structure PS may be disposed between the cell array structure CS and the semiconductor substrate 500, and the semiconductor substrate 500 may be disposed between the peripheral circuit structure PS and the upper insulating layer 700. The through-substrate via 710 may penetrate the upper insulating layer 700 and the semiconductor substrate 500 along the first direction D1, and may be connected (e.g., electrically connected) to a corresponding one of the peripheral wirings 510 by penetrating a portion of the peripheral insulating layer 520 in the first direction D1. The through-substrate via 710 may be spaced apart from the semiconductor substrate 500 with the insulating spacer 720 therebetween. The input/output pad 730 may be electrically connected to the corresponding peripheral wiring 510 through the through-substrate via 710.

The lower substrate 600 may be a semiconductor substrate, and may be, for example, a silicon substrate, a silicon-germanium substrate, a germanium substrate, or a monocrystalline epitaxial layer grown on a monocrystalline silicon substrate. The lower insulating layer 610, the upper insulating layer 700, and the insulating spacer 720 may include an insulating material such as silicon oxide, silicon nitride, silicon oxynitride, and/or a low dielectric material. The through-substrate via 710 and the input/output pad 730 may include a conductive material such as a metal.

Except for the differences described above, the three-dimensional semiconductor memory device according to the present embodiments is substantially the same as the three-dimensional semiconductive memory device described with reference to FIGS. 5 to 8.

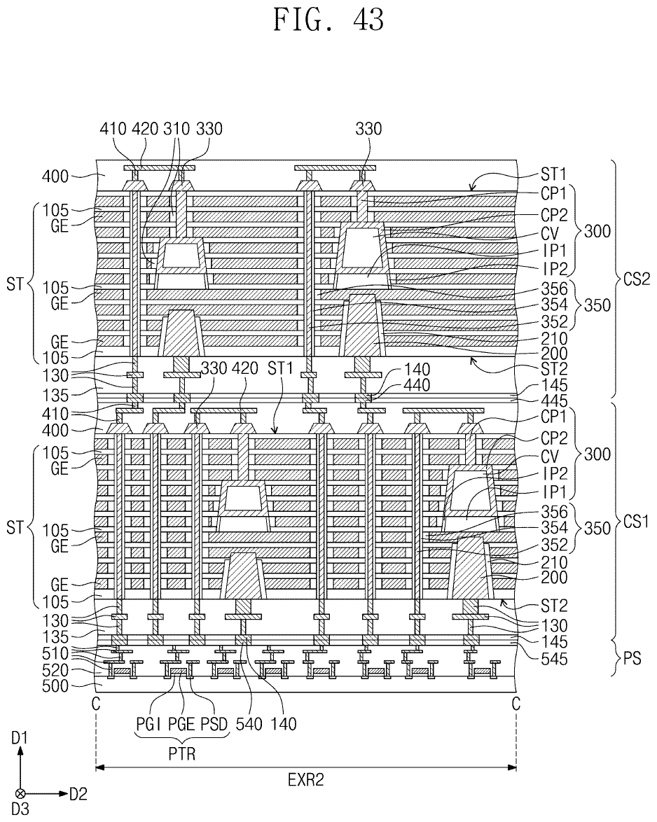

FIG. 43 is a cross-sectional view corresponding to the line C-C′ of FIG. 5 for illustrating a three-dimensional semiconductor memory device according to some embodiments of the disclosed concepts. For simplicity of description, differences from the three-dimensional semiconductor memory device described with reference to FIGS. 5 to 8 will be mainly described.

Referring to FIG. 43, according to some embodiments, a three-dimensional semiconductor memory device may include the semiconductor substrate 500 and the peripheral circuit structure PS on the semiconductor substrate 500, and may further include a first cell array structure CS1 and a second cell array structure CS2 stacked on the peripheral circuit structure CS in the first direction D1. The first cell array structure CS1 may be disposed between the peripheral circuit structure PS and the second cell array structure CS2.

The first cell array structure CS1 may be configured substantially the same as the cell array structure CS described with reference to FIGS. 5-8, except that it further includes additional through electrode structures 350 for electrical connection of the second cell array structure CS2 and the peripheral circuit structure PS. The first cell array structure CS1 may be disposed such that the rear surface ST2 of the stacked structure ST of the first cell array structureCS1 faces the peripheral circuit structure PS. The cell bonding pads 140 of the first cell array structure CS1 may be in contact with the peripheral bonding pads 540 of the peripheral circuit structure PS, and the cell bonding insulating layer 145 of the first cell array structure CS1 may contact the peripheral bonding insulating layer 545 of the peripheral circuit structure PS. The first cell array structure CS1 and the peripheral circuit structure PS may be bonded to one another by the cell bonding pads 140, the peripheral bonding pads 540, the cell bonding insulating layer 145, and the peripheral bonding insulating layer 545.

According to some embodiments, the first cell array structure CS1 may further include upper cell bonding pads 440 and an upper cell bonding insulating layer 445 disposed on the first interlayer insulating layer 400. The upper cell bonding insulating layer 445 may cover side surfaces of the upper cell bonding pads 440 and may expose top surfaces of the upper cells bonding pads 440. The upper cell bonding insulating layer 445 may include, for example, an insulating material such as silicon oxide, silicon nitride, silicon oxynitride, and/or a low dielectric material. The upper cell bonding pads 440 may include a conductive material such as a metal. The upper cell bonding pads 440 may be connected (e.g., electrically connected) to the first wiring patterns 410 and 420 of the first cell array structure CS1.

The second cell array structure CS2 may be configured substantially the same as the cell array structure CS described with reference to FIGS. 5 to 8. The second cell array structure CS2 may be disposed such that the rear surface ST2 of the stacked structure ST of the second cell array structure CS2 faces the front surface ST1 of the stacked structure ST of the first cell array structure CS1. The cell bonding pads 140 of the second cell array structure CS2 may contact the upper cell bonding pads 440 of the first cell array structure CS1, and the cell bonding insulating layer 145 of the second cell array structure CS2 may be in contact with the upper cell bonding insulating layer 445 of the first cell array structure CS1. The first cell array structure CS1 and the second cell array structure CS2 may be bonded to one another by the cell bonding pads 140, the upper cell bonding pads 440, the cell bonding insulating layer 145, and the upper cell bonding insulating layer 445.

The second wiring patterns 130 of the second cell array structure CS2 may be electrically connected to the additional through electrode structures 350 of the first cell array structure CS1 through the cell bonding pads 140 of the second cell array structure CS2, and the upper cell bonding pads 440, the first wiring patterns 410 and 420, and the buried conductive patterns 330, of the first cell array structure CS1. The additional through electrode structures 350 of the first cell array structure CS1 may be electrically connected to the peripheral circuit structure PS through the second wiring patterns 130 of the first cell array structure CS1. That is, the second cell array structure CS2 may be electrically connected to the peripheral circuit structure PS through the second wiring patterns 130 of the second cell array structure CS2 and the upper cell bonding pads 440, the first wiring patterns 410 and 420, the buried conductive patterns 330, the additional through electrode structures 350, and the second wiring patterns 130, of the first cell array structure CS1.

The first conductive contact 300 of the second cell array structure CS2 may be electrically connected to the peripheral circuit structure PS through the buried conductive patterns 330, the first wiring patterns 410 and 420, the through-electrode structure 350, the second wiring patterns 130, and the cell bonding pads 140, of the second cell array structure CS2, and the upper cell bonding pads 440, the first wiring pattern 410 and 420, the buried conductive pattern 330, the additional through-electrode structure 350, and the second wiring pattern 130, of the first cell array structure CS1. The second conductive contact 200 of the second cell array structure CS2 may be electrically connected to the peripheral circuit structure PS through the second wiring patterns 130 and the cell bonding pads 140, of the second cell array structure CS2, and the upper cell bonding pads 440, the first wiring patterns 410 and 420, the buried conductive patterns 330, the additional through electrode structure 350, and the second wiring patterns 130, of the first cell array structure CS1.

Except for the differences described above, the three-dimensional semiconductor memory device according to the present embodiments is substantially the same as the three-dimensional semiconductive memory device described with reference to FIGS. 5 to 8.

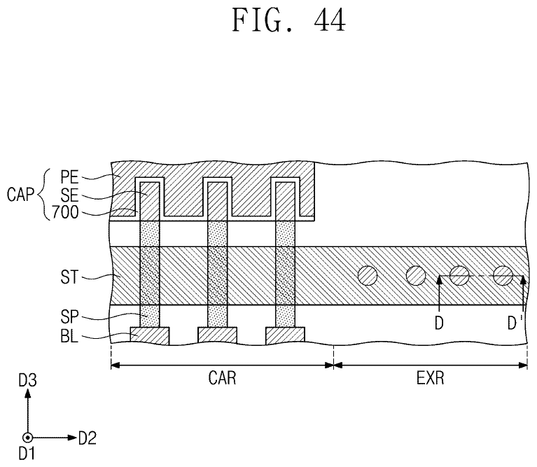

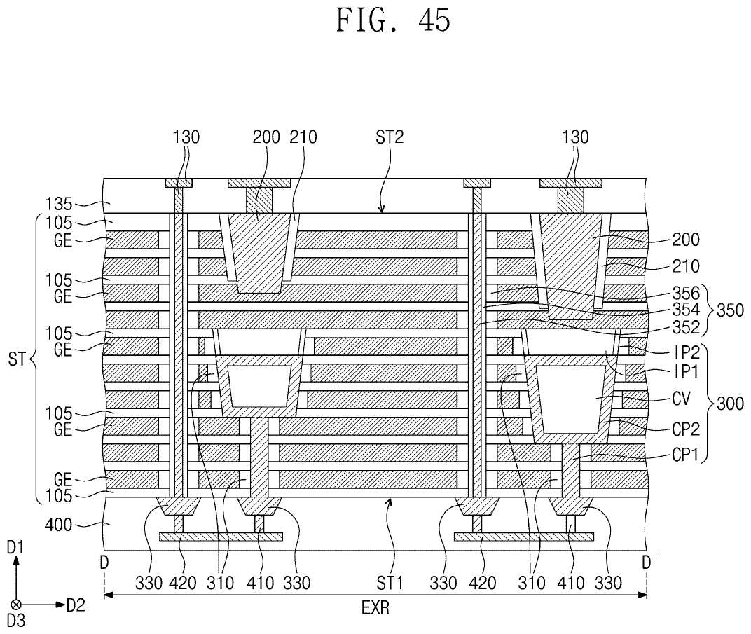

FIG. 44 is a plan view for illustrating a three-dimensional semiconductor memory device according to some embodiments of the disclosed concepts. FIG. 45 is a cross-sectional view taken along a line D-D′ of FIG. 44.

Referring to FIGS. 44 and 45, a three-dimensional semiconductor memory device may include a first interlayer insulating layer 400, a stacked structure ST on the first interlayer insulating layer 400, and a second interlayer insulating layer 135 on the stacked structure ST.

The stacked structure ST may include insulating layers 105 and gate electrodes GE alternately stacked along the first direction D1, and may extend in the second direction D2 and the third direction D3. The first direction D1 may be perpendicular to an upper surface 400U of the first interlayer insulating layer 400, and the second direction D2 and the third direction D3 may be parallel to the upper surface 400U and may intersect with one another. The stacked structure ST may include a cell region CAR and an extension region EXR extending from the cell region CAR in the second direction D2.

The insulating layers 105 and the gate electrodes GE of the stacked structure ST may extend parallel to one another along the second direction D2 in the cell region CAR and the extension region EXR. The stacked structure ST may have a front surface ST1 and a rear surface ST2 opposite to one another in the first direction D1. A height of the front surface ST1 of the extension region EXR of the stacked structure ST may be the same as a height of the front surface ST1 of the cell region CAR of the stacked structure ST. A height of the rear surface ST2 of the extension region EXR of the stacked structure ST may be the same as a height of the rear surface ST2 of the cell region CAR of the stacked structure ST. The height is a distance measured in the first direction D1 from the upper surface 400U of the first interlayer insulating layer 400. That is, the cell region CAR and the extension region EXR of the stacked structure ST may not have a stepped structure.

The insulating layers 105 may include a silicon oxide layer and/or a low dielectric layer. The gate electrodes GE may include, for example, at least one selected from a doped semiconductor (ex, doped silicon, etc.), a metal (ex, tungsten, copper, aluminum, etc.), a conductive metal nitride (ex, titanium nitride, tantalum nitride, etc.), or a transition metal (ex, titanium, tantalum, etc.). The first interlayer insulating layer 400 and the second interlayer insulating layer 135 may include an insulating material such as silicon oxide, silicon nitride, silicon oxynitride, and/or a low dielectric material.

The three-dimensional semiconductor memory device may further include horizontal semiconductor patterns SP disposed in the cell region CAR of the stacked structure ST. The horizontal semiconductor patterns SP may be spaced apart from one another in the first direction D1 and the second direction D2. Among the horizontal semiconductor patterns SP, horizontal semiconductor patterns SP spaced apart from one another in the first direction D1 may extend in the third direction D3 and penetrate the gate electrodes GE, respectively. Among the horizontal semiconductor patterns SP, horizontal semiconductor patterns SP spaced apart from one another in the second direction D2 may extend in the third direction D3 to penetrate a corresponding gate electrode GE among the gate electrodes GE. The horizontal semiconductor patterns SP may include an impurity-doped semiconductor material, an intrinsic semiconductor material in an impurity undoped state, or a polycrystalline semiconductor material.

The three-dimensional semiconductor memory device may further include storage electrodes SE respectively connected to ends of the horizontal semiconductor patterns SP, a plate electrode PE covering the storage electrodes SE, and a dielectric layer 700 between each of the storage electrodes SE and the plate electrode PE. The storage electrodes SE, the plate electrode PE, and the dielectric layer 700 may constitute a capacitor CAP. The storage electrodes SE and the plate electrode PE may include at least one of impurity-doped silicon (Si), impurity-doped silicon germanium (SiGe), a metal (e.g., Ti, Mo, W, Cu, Al, Ta, Ru, Ir, Co, Pt, Au, Ag, or the like), a metal nitride (e.g., a nitride of Ti, Mo, W, Cu, A1, Ta, Ru, Ir, Co, Pt, Au, Ag or the like), titanium silicon nitride (for example, TiSiN), titanium aluminum nitride (such as TiAIN), tantalum aluminum nitrides (such as TaAIN, or the like), a conductive oxide (for example, PtO, RuO₂, IrO₂, SRO (SrRuO₃), BSRO ((Ba,Sr)RuO₃) and CRO (CaRuO₃) or LSCo) or a metal silicide. The dielectric layer 700 may include at least one of a metal oxide such as HfO₂, ZrO₂, Al₂O₃, La₂O₃, Ta₂O₃, and TiO₂, or a dielectric material having a perovskite structure such as SrTiO₃ (STO), (Ba, Sr)TiO₃(BST), BaTiO₃, PZT, and PLZT.

The three-dimensional semiconductor memory device may further include bit lines BL connected to opposite ends of the horizontal semiconductor patterns SP. The bit lines BL may extend in the first direction D1 and may be spaced apart from one another in the second direction D2. The horizontal semiconductor patterns SP spaced apart from one another in the first direction D1 may be connected to a corresponding one of the bit lines BL. The horizontal semiconductor patterns SP spaced apart from one another in the second direction D2 may be respectively connected to the bit lines BL. The capacitor CAP may be spaced apart from the bit lines BL in the third direction D3 with the horizontal semiconductor patterns SP and the stacked structure ST interposed therebetween.

The horizontal semiconductor patterns SP and the gate electrodes GE may constitute transistors, and the horizontal semiconductor patterns SP may be used as channels of the transistors. The three-dimensional semiconductor memory device according to the present embodiments may constitute a dynamic random access memory (DRAM) device.

The three-dimensional semiconductor memory device may further include a first conductive contact 300 and a second conductive contact 200 disposed in the extension region EXR of the stacked structure ST and spaced apart from one another in the first direction D1, side insulating patterns 310 on a side surface of the first conductive contact 300, and a side insulating spacer 210 on a side surface the second conductive contact 200. The first conductive contact 300, the second conductive contact 200, the side insulating patterns 310 and the side insulating spacer 210 are substantially the same as the first conductive contact 300 and the second conductive contacts 200, the side insulation patterns 310 and the side insulating spacer 210 described with reference to FIGS. 5 to 8.

The three-dimensional semiconductor memory device may further include a through-electrode structure 350 disposed in the extension region EXR of the stacked structure ST. The through electrode structure 350 is substantially the same as the through electrode structure 350 described with reference to FIGS. 5-8.

The first interlayer insulating layer 400 may be disposed on the front surface ST1 of the stacked structure ST. The three-dimensional semiconductor memory device may further include buried conductive patterns 330 and first wiring patterns 410 and 420 disposed on the front surface ST1 of the stacked structure ST and in the first interlayer insulating layer 400. The buried conductive patterns 330 may be disposed on the first conductive contact 300 and the through-electrode structure 350, respectively, and may be connected (e.g., electrically connected) to the first conductive contact 300 and the through electrode structure 350, respectively. The first wiring patterns 410 and 420 may include first wiring contacts 410 connected (e.g., electrically connected) to the buried conductive patterns 330, and first wiring lines 420 connected to the first wiring contacts 410. The buried conductive patterns 330 and the first wiring patterns 410 and 420 are substantially the same as the buried conductive patterns 330 and the first wiring patterns 410 and 420 described with reference to FIGS. 5 to 8.

The second interlayer insulating layer 135 may be disposed on the rear surface ST2 of the stacked structure ST. The three-dimensional semiconductor memory device may further include second wiring patterns 130 disposed on the rear surface ST2 of the stacked structure ST and in the second interlayer insulating layer 135. The second conductive contact 200 and the through electrode structure 350 may be respectively connected (for example, electrically connected) to corresponding second wiring patterns 130 among the second wiring patterns 130. The first conductive contact 300 may be electrically connected to the second wiring patterns 130 through the buried conductive patterns 330, the first wiring patterns 410 and 420, and the through electrode structure 350.

According to embodiments of the disclosed concepts, a first conductive contact and a second conductive contact may be disposed within an extension region of a stacked structure including gate electrodes stacked in a vertical direction and may be spaced apart from one another in the vertical direction. The first conductive contact and the second conductive contact may be respectively connected (e.g., electrically connected) to gate electrodes located at different heights. Some of the gate electrodes of the stacked structure may be respectively connected (e.g., electrically connected) to a plurality of first conductive contacts, and the rest of the gate electrodes in the stacked structure may be respectively connected (e. g., electrically connected) to a plurality of second conductive contacts. Within the extension region of the stacked structure, the plurality of first conductive contacts may be vertically spaced apart from the plurality of second conductive contacts along the vertical direction. In this case, the first and second conductive contacts connected to the gate electrodes may be efficiently disposed within a limited area of the extension region of the stacked structure. In addition, when the number of the gate electrodes of the stacked structure increases, an increase in an area of the extension region of the stacked structure, for placement of conductive contacts connected (e.g., electrically connected) to the gate electrodes, may be minimized.

Accordingly, a three-dimensional semiconductor memory device that is easy to be highly integrated and an electronic system including the same may be provided.

According to embodiments of the disclosed concepts, a method of manufacturing a three-dimensional semiconductor memory device may include forming a mold structure including insulating layers and sacrificial layers alternately stacked along a first direction, forming a first vertical hole through the mold structure along the first direction, forming a first contact hole by etching an upper portion of the mold structure, exposed by the first vertical hole, forming first recess regions laterally recessing the sacrificial layers exposed by the first contact hole and the first vertical hole, forming side insulating patterns filling the first recess regions, and forming a first conductive contact filling the first vertical hole and the first contact hole. A width in a second direction of the first contact hole may be greater than a width in the second direction of the first vertical hole, and the second direction may be perpendicular to the first direction.

According to some embodiments, the first conductive contact may include a first contact portion filling the first vertical hole, and a second contact portion filling the first contact hole. A width in the second direction of the second contact portion may be greater than a width in the second direction of the first contact portion.

According to some embodiments, the first conductive contact may further include a void formed inside the second contact portion.

According to some embodiments, forming the side insulating patterns and the first conductive contacts may include forming a first insulating layer that fills the first recess regions and covers inner surfaces of the first vertical hole and the first contact hole, forming a first contact sacrificial layer that fills a remainder of the first vertical hole and a portion of the first contact hole, forming a second insulating layer that fill a remainder of the second contact holes, removing the first contact sacrificial layer in the first vertical hole and the first contact hole, removing a portion of the first insulating layer in the first vertical hole and the first contact hole, and forming a conductive layer that fills the first vertical hole and fills a remainder of first contact hole.

According to some embodiments, the method may further include alternately stacking additional sacrificial layers and additional insulating layers on the mold structure prior to forming the side insulating patterns and the first conductive contact, and forming a second contact hole penetrating the additional sacrificial layers and the additional insulating layers along the first direction. The first contact hole and the second contact hole may be spaced apart from one another along the first direction.

According to some embodiments, the method may further include forming a side insulating spacer that fills a portion of the second contact hole, and a second conductive contact that fills a remainder of the second contact hole.

According to some embodiments, the method may further include replacing the sacrificial layers with gate electrodes prior to forming the side insulating patterns, the first conductive contact, the side insulating spacer, and the second conductive contact.

According to some embodiments, the first conductive contact may be connected to a first gate electrode of the gate electrodes, and the second conductive contact may be connected to a second gate electrode of the gate electrodes. The first gate electrode and the second gate electrode may be positioned at different heights.

According to some embodiments, the first conductive contact and the second conductive contact may be spaced apart from one another in the first direction and may be aligned with one another in the first direction.

According to some embodiments, forming the side insulating spacer and the second conductive contact may include: forming an insulating layer covering an inner surface of the second contact hole and filling a portion of the second contact hole, forming a contact sacrificial layer filling a remainder of the second contact hall, removing the contact sacrificial layer and a portion of the insulating layer to form an inner hole in the second contact hole, and forming the second conductive contact filling the inner hole. The inner hole may pass through the insulating layer along the first direction, and a remainder of the insulating layer may be the side insulating spacer.

While embodiments are described above, a person skilled in the art may understand that many modifications and variations are made without departing from the spirit and scope of the disclosed concepts defined in the following claims. Accordingly, the example embodiments of the disclosed concepts should be considered in all respects as illustrative and not restrictive, with the spirit and scope of the disclosed concepts being indicated by the appended claims.

What is claimed is:

1. A three-dimensional semiconductor memory device, comprising:
a stacked structure including insulating layers and gate electrodes alternately stacked along a first direction, the stacked structure including a cell region and an extension region extending from the cell region in a second direction perpendicular to the first direction;
a vertical structure disposed in the cell region of the stacked structure and penetrating the stacked structure along the first direction; and
a first conductive contact and a second conductive contact disposed in the extension region of the stacked structure and spaced apart from one another in the first direction,
wherein the first conductive contact penetrates a portion of the stacked structure along the first direction and is connected to a first gate electrode of the gate electrodes,
wherein the second conductive contact penetrates another portion of the stacked structure along the first direction and is connected to a second gate electrode of the gate electrodes, and
wherein the first conductive contact includes a first contact portion penetrating the first gate electrode along the first direction and spaced apart from the first gate electrode, and a second contact portion disposed on a surface of the first gate electrode and connected to the surface of the first gate electrode, and
wherein a width of the second contact portion in the second direction is greater than a width of the first contact portion in the second direction.

2. The 3D semiconductor memory device of claim 1, wherein the first gate electrode and the second gate electrode are positioned at different heights along the first direction.

3. The 3D semiconductor memory device of claim 1, wherein:
the first gate electrode has a first surface and a second surface opposite to one another in the first direction, and
the first contact portion penetrates a portion of the stacked structure on the first surface of the first gate electrode, and
the second contact portion penetrates a portion of the stacked structure on the second surface of the first gate electrode, and is connected to the second surface.

4. The 3D semiconductor memory device of claim 1, further comprising:
side insulating patterns interposed between the first conductive contact and the stacked structure,
wherein the side insulating patterns are interposed between the insulating layers and spaced apart from one another in the first direction.

5. The 3D semiconductor memory device of claim 1, further comprising:
a side insulating spacer interposed between the second conductive contact and the stacked structure and extending in the first direction.

6. The 3D semiconductor memory device of claim 1, wherein the stacked structure has a front surface and a rear surface opposite to one another in the first direction, and
the device further comprising:
first wiring patterns on the front surface of the stacked structure; and
second wiring patterns on the rear surface of the stacked structure,
wherein:
the first contact portion of the first conductive contact extends toward the front surface of the stacked structure and is connected to a corresponding first wiring pattern among the first wiring patterns, and
the second conductive contact extends toward the rear surface of the stacked structure and is connected to a corresponding second wiring pattern among the second wiring patterns.

7. The 3D semiconductor memory device of claim 6, further comprising a through-electrode structure disposed in the extension region of the stacked structure and penetrating the stacked structure along the first direction,
wherein the first conductive contact is connected to the through electrode structure through the first wiring patterns.

8. The 3D semiconductor memory device of claim 7, wherein the through electrode structure is connected to a corresponding second wiring pattern among the second wiring patterns.

9. The 3D semiconductor memory device of claim 8, further comprising:
a peripheral circuit structure disposed on the rear surface of the stacked structure, wherein
the second wiring patterns are disposed between the rear surface of the stacked structure and the peripheral circuit structure, and
the through electrode structure and the second conductive contact are connected to the peripheral circuit structure through the second wiring patterns.

10. The 3D semiconductor memory device of claim 1, wherein the first conductive contact and the second conductive contact are vertically aligned with one another along the first direction.

11. The 3D semiconductor memory device of claim 1, wherein the first conductive contact further comprises a void inside the second contact portion.

12. The 3D semiconductor memory device of claim 1, wherein the first conductive contact and the second conductive contact are offset from one another along the second direction.

13. A three-dimensional semiconductor memory device, comprising:
a stacked structure including insulating layers and gate electrodes alternately stacked along a first direction, the stacked structure having a front surface and a rear surface opposite to one another in the first direction;
a first conductive contact extending from the front surface of the stacked structure into the stacked structure, penetrating a portion of the stacked structure along the first direction, and connected to a first gate electrode of the gate electrodes;
side insulating patterns interposed between the first conductive contact and the stacked structure and between the insulating layers, and spaced apart from one another in the first direction;
a second conductive contact extending from the rear surface of the stacked structure into the stacked structure penetrating another portion of the stacked structure along the first direction, and connected to a second gate electrode of the gate electrodes; and
a side insulating spacer interposed between the second conductive contact and the stacked structure and extending in the first direction.

14. The 3D semiconductor memory device of claim 13, wherein the first gate electrode and the second gate electrode are positioned at different heights along the first direction.

15. The 3D semiconductor memory device of claim 13, wherein: the first gate electrode has a first surface and a second surface opposite to one another in the first direction, the first surface faces the front surface of the stacked structure, and the second surface faces the rear surface of the stacked structures; and
the first conductive contact comprises:
a first contact portion penetrating the first surface of the first gate electrode and the first gate electrode, the first contact portion being spaced apart from the first gate electrode with a corresponding one of the side insulating patterns interposed therebetween; and
a second contact portion disposed on the second surface of the first gate electrode and connected to the second surface.

16. The 3D semiconductor memory device of claim 15, wherein:
a width of the second contact portion in a second direction is greater than a width of the first contact portion in the second direction, and
the second direction is parallel to the front surface and the rear surface of the stacked structure.

17. The 3D semiconductor memory device of claim 16, wherein the second contact portion extends from the second surface of the first gate electrode in the first direction to penetrate through corresponding gate electrodes of the gate electrodes, and is spaced apart from the corresponding gate electrodes with corresponding ones among the side insulating patterns interposed therebetween.

18. The 3D semiconductor memory device of claim 13, wherein the side insulating spacer extends along the first direction to penetrate corresponding ones of the gate electrodes and corresponding ones of the insulating layers.

19. The 3D semiconductor memory device of claim 13, further comprising:
first wiring patterns on the front surface of the stacked structure;
second wiring patterns on the rear surface of the stacked structure; and
a through-electrode structure penetrating the stacked structure along the first direction and connected to the first wiring patterns and the second wiring patterns,
wherein the first conductive contact is connected to the first wiring patterns, and the second conductive contact is connected to the second wiring patterns.

20. A three-dimensional semiconductor memory device, comprising:
a stacked structure including gate electrodes spaced apart from one another in a first direction and extending parallel to one another in a second direction perpendicular to the first direction, the stacked structure having a front surface and a rear surface opposite to one another in the first direction;
a first conductive contact extending from the front surface of the stacked structure into the stacked structure, extending along the first direction to penetrate corresponding ones of the gate electrodes, and connected to a first gate electrode of the gate electrodes;
side insulating patterns interposed between the first conductive contact and the corresponding gate electrodes and spaced apart from one another in the first direction;
a second conductive contact extending from the rear surface of the stacked structure into the stacked structure, extending along the first direction to penetrate other corresponding ones of the gate electrodes, and connected to a second gate electrode of the gate electrodes; and
a side insulating spacer extending in the first direction between the second conductive contact and the other corresponding gate electrodes.
